(19) United States
(12) Patent Application Publication
(10) Pub. No.: US 2015/0366073 A1
(43) Pub. Date: Dec. 17, 2015

(54) THREE-DIMENSIONAL CONDUCTIVE PATTERNS AND INKS FOR MAKING SAME

(71) Applicant: YISSUM RESEARCH DEVELOPMENT COMPANY OF THE HEBREW UNIVERSITY OF JERUSALEM, Jerusalem (IL)

(72) Inventors: Shlomo MAGDASSI, Jerusalem (IL); Amir SHAPIRA, Herzliya (IL); Michael LAYANI, Jerusalem (IL); Ido COOPERSTEIN, Haifa (IL)

(21) Appl. No.: 14/764,378

(22) PCT Filed: Jan. 30, 2014
(86) PCT No.: PCT/IL2014/050110

§ 371 Date: Jul. 29, 2015

Related U.S. Application Data
(60) Provisional application No. 61/759,091, filed on Jan. 31, 2013.

(51) Int. Cl. H05K 3/12; H05K 1/02; B29C 67/00

(52) U.S. Cl. CPC H05K 3/125; B29C 67/0059; B29C 67/0066; H05K 1/0296; B29K 2105/0002

(57) ABSTRACT

The invention generally relates to polymerizable conductive ink formulations comprising at least one metal source, at least one monomer and/or oligomer and a polymerization initiator, and uses thereof for printing three-dimensional functional structures. In particular a method of fabricating a three-dimensional conductive pattern on a substrate is disclosed, the method comprising: a) forming a pattern on a surface region of a substrate by using an ink comprising at least one metal source, at least one liquid polymerizable monomer and/or oligomer, and at least one polymerization initiator; b) polymerizing at least a portion of said liquid monomer and/or oligomer; c) rendering the metal source a continuous percolation path for electrical conductivity (sintering); d) repeating steps (a), (b) and optionally (c) to obtain a three-dimensional conductive pattern.

### TECHNOLOGICAL FIELD

The invention generally relates to polymerizable conductive ink formulations and uses thereof for printing three-dimensional functional structures.

### BACKGROUND OF THE INVENTION

Digital printing, typically known as digital fabrication, enables fabrication of various functional coatings and devices, and provides the ability to create three-dimensional (3D) structures and patterns with high aspect ratios.

Digital printing is known in the art to afford functional coatings of electrodes for devices, such as sensors and electroluminescent devices. Sriprachuabwong et al. [1] describes printed polyaniline electrodes as ascorbic acid sensors and Azouble et al. [2] describes printed carbon nanotubes as electrodes for electroluminescent devices.

Printed electronics mainly focuses on conducting patterns which are formed by printing nanoparticles and precursors; among these, the most common are silver inks which are mainly used for the fabrication of simple 2-dimensional conductive patterns [3]. One of the obstacles towards achieving high aspect ratio of the printed pattern is the flow of the ink on the substrate due to inappropriate ink viscosity and surface tension.

Kullman et al. [4] describes 3D conductive structures by ink-jet printing of many layers of low viscosity gold dispersion in toluene, while fixing the individual layers by rapid evaporation of the solvent. The electrical conductivity, after heating to above 180° C., was about 4 orders of magnitude smaller than that of bulk gold.

Ahn et al. [5] describes omni-directional printing of viscous silver dispersions (>70% Ag), which due to their rheological properties, did not spread on the substrate. In this filamentary printing approach the concentrated ink was extruded through a tapered cylindrical nozzle that was moved using three axis motion control stage. The printing resulted in aspect ratios of up to 7, depending of the number of printed layers. The resulting patterns were heated to 250° C. yielding a resistivity of about 3% bulk silver.

Since ink-jet printing is a rapid fabrication method, the main requirement for the ink formulation is for it to be a low viscosity ink.

Willis et al. [6] describes a method, wherein inks containing non-volatile monomers and photoinitiators were exposed to UV radiation immediately after printing, causing conversion of the liquid monomers into a solid polymer (UV inks). When such printing was conducted with many layers, with each layer being exposed to radiation causing polymerization to occurr rapidly, large 3D structures, as large as 50×40×20 cm, could be produced [7].

Sangermano et al. reported UV polymerizable inks containing silver nanoparticles, water and polyethylenglycol diacrylate monomers [8]. It was found that for a mixture containing at least 30% silver, the resistivity of films prepared by a wire-wound applicator was about 9 orders of magnitude higher than that of bulk silver. This very low resistivity was due to the presence of the polymeric matrix of the ink after UV exposure.

In general, printing of metallic material is only the first step towards obtaining a conductive pattern which should be followed by an additional step of sintering nanoparticles. This can be achieved by conventional thermal heating, which causes burning of the organic material that functions as an insulator, or by either plasma [9], microwave [10], LASER [11] radiation.

Recently, Magdassi et al. reported on a simple low temperature sintering method of silver nanoparticles, which is based on ligand exchange mechanism [12]. This process was performed by simple dipping [13] of the printed substrate in NaCl solution, or by printing the solution on top of the nanoparticles' pattern [14]. This process can result in high conductivity of about 20% bulk silver.

### REFERENCES

[1] Sriprachuabwong, C.; Karuwan, C.; Wisitsorrat, A.; Phokharatkul, D.; Lomas, T.; Sritongkham, P.; Tuantranont, A. Journal of Materials Chemistry 2012, 22 (12), 5478-5485.
[2] Azoubel, S.; Shemesh, S.; Magdassi, S Nanotechnology 2012, 23 (34).
[3] (a) Tekin, E.; Smith, P. J.; Schubert, U. S., Ink-jet printing as a deposition and patterning tool for polymers and inorganic particles. Soft Matter 2008, 4 (4), 703-713; (b) Grouchko, M.; Kamyshny, A.; Magdassi, S Journal of Materials Chemistry 2009, 19 (19), 3057-3062.
[4] Kullmann, C.; Schirmer, N. C.; Lee, M. T.; Ko, S. H.; Hotz, N.; Grigoropoulos, C. P.; Poulikakos, D. Journal of Micromechanics and Microengineering 2012, 22 (5).
[5] Ahn, B. Y.; Duoss, E. B.; Motala, M. J.; Guo, X. Y.; Park, S. I.; Xiong, Y. J.; Yoon, J.; Nuzzo, R. G.; Rogers, J. A.; Lewis, J. A Science 2009, 323 (5921), 1590-1593.
[6] Willis, K. Proceedings of the 25th annual ACM symposium on User interface software and technology 2012, ACM, 2012.
[7] http://objet.com/.
[8] Chiolerio, A.; Vescovo, L.; Sangermano, M Macromolecular Chemistry and Physics 2010, 211 (18), 2008-2016.
[9] Reinhold, I.; Hendriks, C. E.; Eckardt, R.; Kranenburg, J. M.; Perelaer, J.; Baumann, R. R.; Schubert, U. S. Journal of Materials Chemistry 2009, 19 (21), 3384-3388.
[10] Perelaer, J.; Jani, R.; Grouchko, M.; Kamyshny, A.; Magdassi, S.; Schubert, U. S. Advanced Materials 2012, 24 (29), 3993-3998.
[11] Chung, J. W.; Ko, S. W.; Bieri, N. R.; Grigoropoulos, C. P.; Poulikakos, D. Applied Physics Letters 2004, 84 (5), 801-803.
[12] Magdassi, S.; Grouchko, M.; Berezin, O.; Kamyshny, A. Acs Nano 2010, 4 (4), 1943-1948.
[13] (a) Grouchko, M.; Kamyshny, A.; Mihailescu, C. F.; Anghel, D. F.; Magdassi, S. Acs Nano 2011, 5 (4), 3354-3359; (b) Tang, Y.; He, W.; Zhou, G. Y.; Wang, S. X.; Yang, X. J.; Tao, Z. H.; Zhou, J. C. Nanotechnology 2012, 23 (35).
[14] Layani, M.; Grouchko, M.; Shemesh, S.; Magdassi, S. Journal of Materials Chemistry 2012, 22 (29), 14349-14352.

### SUMMARY OF THE INVENTION

An objective of the invention is to provide a novel printing process for producing 3-dimentional (3D) conductive structures and patterns on a surface of a substrate, by performing repetitive layer printing, curing and sintering and/or reduction processes of any one or more of said layers. Each printed layer comprises a metallic source, e.g., plurality of nanoparticles, and a liquid carrier made of a liquid polymerizable monomer and/or oligomer, and at least one polymerization initiator which under the process conditions allow polymerization of the polymerizable components (monomer and/or oligomer).

The metallic nanoparticles or metallic microparticles may be in the form of a powder or may be contained in a dispersion, which may be an aqueous dispersion or an oil-based dispersion (e.g., monomers and/or oligomers and or a volatile solvent), or in an emulsion, and may additionally include formulation aides such as dispersion stabilizers, emulsifiers, wetting and rheological additives.

The method of the invention comprises optionally consecutive steps. The first step includes the printing, on a surface of a substrate, a pattern of a formulation comprising the polymerizable liquid carrier containing a metallic source and subsequently polymerizing the polymerizable components under conditions which permit polymerization of only an amount of said components. Thereafter, the partially or fully cured printed pattern is optionally subjected to an additional step rendering the metal source a continuous percolation path to permit electrical connectivity between the nanoparticles or microparticles, to thereby obtain the desired conductive pattern or structure.

In order to achieve efficient 3D printing of patterns having high aspect ratio, the printing and curing steps and optionally the sintering step, are performed for one or more times, enabling to vertically increase the pattern height with each consecutive printed layer, without substantially increasing the width of the pattern (i.e., thus resulting in high aspect ratio).

Thus in one aspect, the invention provides a method of printing a three-dimensional conductive pattern on a surface region of a substrate, the method comprising:
a) forming a pattern on a surface region of a substrate; wherein said pattern comprising at least one metal source, at least one liquid polymerizable monomer and/or oligomer, and at least one polymerization initiator; the pattern optionally further comprises at least one solvent being insoluble with said at least one liquid polymerizable monomer and/or oligomer, said solvent being, in some embodiments, water;
b) affecting polymerization of at least a portion of said at least one liquid polymerizable monomer and/or oligomer;
c) rendering the metal source a continuous percolation path for electrical conductivity; (i.e., converting the pattern containing the at least one metal source to a continuous conductive metal pattern or structure by sintering in case of nanoparticles and/or microparticles; or by reduction and optionally sintering in case of a metal precursor);
d) repeating steps (a), (b) and optionally (c) for one or more times to obtain a three-dimensional conductive pattern.

In some embodiments, steps a, b and optionally c are repeated one or more times to obtain a three-dimensional conductive pattern, wherein said pattern is characterized by an aspect ratio in the range of 0.5 to 100.

In some embodiments, the three-dimensional pattern is a three-dimensional object which may be detached from the substrate surface.

In some embodiments, the method as herein described further comprises the step of obtaining an ink formulation comprising at least one metal source, e.g., in the form of metallic nanoparticles, metallic microparticles or metal precursors, at least one liquid polymerizable monomer and/or oligomer, and at least one polymerization initiator for affecting polymerization of said at least one liquid polymerizable monomer and/or oligomer.

The method may be employed by a sequential repetition of steps (a), (b) and (c). In some embodiments, the method includes an initial step (a) of forming, e.g., printing a pattern on the surface of a substrate, and then, an additional step (b) of curing a portion of the polymerizable liquid in said pattern. In order to obtain a 3D conductive pattern, e.g., of a high aspect ratio, or a 3D object, step (c) (rendering the metal source a continuous percolation path for electrical conductivity) may be performed immediately after step (b). Alternatively, the printing and curing steps (steps (a) and (b), respectively) may be sequentially repeated for more than one time before rendering the metal source a continuous percolation path for electrical conductivity.

In some embodiments, step (c) is performed after both steps (a) and (b) are repeated more than 2 times. In other embodiments, step (c) is performed after both steps (a) and (b) are repeated more than 20 times. In further embodiments, step (c) is performed after both steps (a) and (b) are repeated more than 50 times.

Once the pattern or object is formed, e.g., printed on a surface region of a substrate, or on a previously formed pattern, curing of the polymerizable components in said pattern may ensue. As the step of curing is followed by rendering the metal source continuous and conductive, in order to maximize or render efficient the sintering of the nanoparticles in the pattern, the curing of the polymerizable components should not (need not) be carried out to completion, as complete curing may block or prevent the sintering agents from penetrating the pattern and contacting the nanoparticles in the cured polymer.

In some embodiments, when the ink formulation printed is in the form of oil in water (O/W) emulsion, the monomers and/or oligomers may be fully cured, thus may not necessitate further curing. In such O/W formulation, water droplets or bubbles may be present in the emulsion, which would form voids once water is removed. Thus, in such cases, the sintering agent is capable of sintering the metal nanoparticles or microparticles, even if full polymerization occurs.

Therefore, the curing step is carried out to an extent needed based on the formulation used. In some embodiments, only a portion of the polymerizable components (monomers and/or oligomers) are cured, with the majority of the polymerizable components remaining uncured and in substantially liquid form.

Thus, the polymerization step is performed for a time period sufficient to cure a portion of the polymerizable liquid, permitting subsequent penetration of the sintering agent therethrough, as further described below.

In some embodiments, the polymerization step is performed for a time period sufficient to cure between 1% and 100% of said at least one liquid polymerizable monomer and/or oligomer. In some embodiments, the polymerization step is performed for a time period sufficient to cure between 10% and 90% of said at least one liquid polymerizable monomer and/or oligomer. In some embodiments, the polymerization step is performed for a time period sufficient to cure between 20% and 80% of said at least one liquid polymerizable monomer and/or oligomer. In some embodiments, the polymerization step is performed for a time period sufficient to cure between 30% and 70% of said at least one liquid polymerizable monomer and/or oligomer.

In some embodiments, the polymerization step is performed for a time period sufficient to cure between 40% and 60% of said at least one liquid polymerizable monomer and/or oligomer. In some embodiments, the polymerization step is performed for a time period sufficient to cure between 10% and 20% of said at least one liquid polymerizable monomer and/or oligomer.

In some embodiments, the polymerization step is performed for a time period sufficient to cure between 10% and 50% of said at least one liquid polymerizable monomer and/or oligomer. In some embodiments, the polymerization step is performed for a time period sufficient to cure between 20% and 50% of said at least one liquid polymerizable monomer and/or oligomer. In some embodiments, the polymerization step is performed for a time period sufficient to cure between 30% and 50% of said at least one liquid polymerizable monomer and/or oligomer. In some embodiments, the polymerization step is performed for a time period sufficient to cure between 40% and 50% of said at least one liquid polymerizable monomer and/or oligomer.

In some embodiments, the polymerization step is performed for a time period sufficient to cure at least 5%, 10%, 15%, 20%, 25%, 30%, 40%, 50%, 60% or 70%, 80%, 90% or 99% of said at least one liquid polymerizable monomer and/or oligomer.

In some embodiments, the polymerization step is performed for a time period sufficient to cure at least 1%, 2%, 3%, 4%, 5%, 6%, 7%, 8%, 9%, 10%, 11%, 12%, 13%, 14%, 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 48%, 49% or 50% of said at least one liquid polymerizable monomer and/or oligomer.

In some embodiments, where the polymer to be achieved by curing is a hydrophilic polymer, the polymerization step may be carried out to achieve complete (substantially 100%) curing of the polymer, and the sintering step may thereafter be carried out with an aqueous-based or gaseous-based sintering agent enabling penetration of the aqueous or gaseous sintering agents through the polymer.

In some embodiments, the polymerization step is performed for a time period of 1 millisecond to 15 seconds. In some embodiments, the polymerization step is performed for a time period of at least 1 millisecond, 5 milliseconds, 10 milliseconds or at least 20, 30, 40, 50, 60, 70, 80, 90 or 100 milliseconds (or any intermediate time duration).

In some embodiments, the polymerization step is performed for a time period of at most 1,000 milliseconds. In some embodiments, the polymerization step is performed for a time period in the range of 1-20 milliseconds. In some embodiments, the polymerization step is performed for a time period in the range of 1-1,000 milliseconds. In some embodiments, the polymerization step is performed for a time period in the range of 1-500 milliseconds. In some embodiments, the polymerization step is performed for a time period in the range of 500-1,000 milliseconds. In some embodiments, the polymerization step is performed for a time period in the range of 20-50 milliseconds. In some embodiments, the polymerization step is performed for a time period in the range of 100-300 milliseconds.

In some embodiments, the polymerization step is performed for a time period of at least 1 second to 15 seconds. In other embodiments, the polymerization step is performed for a time period in the range of 1 to 5 seconds. In some embodiments, the polymerization step is performed for a time period in the range of 5 to 10 seconds. The time duration of the curing step may be 0.5, 1, 2, 3, 4, 5, 6, 7, 8, 10 or 15 seconds (or any intermediate time duration).

The curing may be achieved by exposing the pattern containing the polymerizable components and the polymerization initiator to a radiation and/or a heat source capable of initiating polymerization of the polymerizable components. The radiation and/or heat source may be selected from a UV source, a laser, an electron beam, a gamma-radiation, an IR (heat) source, LED, microwave radiation, plasma and thermal treatment.

The amount of the metal source in the cured polymer may be between 1% and 99%. In some embodiments, the amount of the metal source in the cured polymer may be between 10% and 90%, between 20% and 90%, between 30% and 90%, between 40% and 90%, between 50% and 90%, between 60% and 90%, between 70% and 90%, or between 80% and 90%.

The amount of the cured polymer in the pattern prior to removal thereof may be between 1% and 99%. In some embodiments, the amount is between 10% and 90%, between 20% and 90%, between 30% and 90%, between 40% and 90%, between 50% and 90%, between 60% and 90%, between 70% and 90%, or between 80% and 90%.

In some embodiments, the radiation source employed for initiating the curing process is selected based on the type of photoinitiator used. Generally, the photoinitiator is a chemical compound that decomposes into free radicals when exposed to light. In some embodiments, the at least one photoinitiator is selected from of ethyl-4-dimethylaminobezoate (EDMAB), 2-isopropylthioxanthon, 2-benzyl-2 dimethylamino-1-94-morpholinophenyl)-butanone, dimethyl-1,2-diphenyllehan-1-one and benzophenon.

In some embodiments, the at least one photoinitiator is dissolved in dipropylenglycol diacrylate (DPGDA), or dipentaerythritol hexa-acrylate (DPHA), or trimethylolpropane triacrylate (TMPTA).

The monomers and oligomers are selected according to their physico-chemical and chemical properties, such as viscosity and surface tension, number of polymerizable groups, and according to the printing method and the polymerization reaction type, e.g., the radiation source or heat source of choice.

In some embodiments, the monomers are selected from acid containing monomers, acrylic monomers, amine containing monomers, crosslinking acrylic monomers, dual reactive acrylic monomers, epoxides/anhydrides/imides, fluorescent acrylic monomers, fluorinated acrylic monomers, high or low refractive index monomers, hydroxy containing monomers, mono and difunctional glycol oligomeric monomers, styrenic monomers, vinyl and ethenyl monomers.

In some embodiments, the monomers can polymerize to yield conductive polymers such as polypyrole and polyaniline. In some embodiments, the at least one monomer is selected from dipentaerythnitol hexaacrylate (DPHA) and trimethylolpropane triacrylate (TMPTA).

In some embodiments, the at least one oligomer is selected from the group consisting of acrylates and vinyl containing molecules.

The at least one metal source used in a method according to the invention is selected amongst metal nanoparticles and/or microparticles; and metal precursors such as metal ions/salts/complexes which may be convertible to metal.

In some embodiments, the at least one metal source is metal nanoparticles or microparticles. The metal nanoparticles employed in accordance with the invention are solid particles having at least one dimension in the nanometer scale, i.e., an average size of between 0.1 and 500 nm. In some embodiments, the metallic nanoparticles have a particle size in the range of 0.1 and 5 nanometers, 1 and 10 nanometers, 10 and 30 nanometers or 10 and 100 nanometers. In some embodiments, the metallic microparticles have a particle size in the range of 1 and 100 micrometers.

In some embodiments, the metallic nanoparticles have a particle size of between 1 and 100 nanometers. In some other embodiments, the metallic nanoparticles have a particle size of between 10 and 40 nanometers. In some embodiments, the metallic nanoparticles have a particle size of between 10 and 20 nanometers.

In some embodiments, the metallic nanoparticles have a particle size of between 1 and 1,000 nanometers. In some other embodiments, the metallic nanoparticles have a particle size of between 100 and 1,000 nanometers. In some embodiments, the metallic nanoparticles have a particle size of between 200 and 1,000 nanometers. In some embodiments, the metallic nanoparticles have a particle size of between 300 and 1,000 nanometers. In some other embodiments, the metallic nanoparticles have a particle size of between 400 and 1,000 nanometers. In some embodiments, the metallic nanoparticles have a particle size of between 500 and 1,000 nanometers. In some embodiments, the metallic nanoparticles have a particle size of between 600 and 1,000 nanometers. In some other embodiments, the metallic nanoparticles have a particle size of between 700 and 1,000 nanometers. In some embodiments, the metallic nanoparticles have a particle size of between 800 and 1,000 nanometers. In some embodiments, the metallic nanoparticles have a particle size of between 900 and 1,000 nanometers.

In some embodiments, the metallic nanoparticles have a particle size of between 1 and 100 nanometers. In some other embodiments, the metallic nanoparticles have a particle size of between 10 and 100 nanometers. In some embodiments, the metallic nanoparticles have a particle size of between 20 and 100 nanometers. In some embodiments, the metallic nanoparticles have a particle size of between 30 and 100 nanometers. In some other embodiments, the metallic nanoparticles have a particle size of between 40 and 100 nanometers. In some embodiments, the metallic nanoparticles have a particle size of between 50 and 100 nanometers. In some embodiments, the metallic nanoparticles have a particle size of between 60 and 100 nanometers. In some other embodiments, the metallic nanoparticles have a particle size of between 70 and 100 nanometers. In some embodiments, the metallic nanoparticles have a particle size of between 80 and 100 nanometers. In some embodiments, the metallic nanoparticles have a particle size of between 90 and 100 nanometers.

Where the nanoparticles are generally in the form of nanospheres, the particle size refers to the diameter of the spheres. Where the nanoparticles are not in the form of a sphere, the particle size refers to the particles shortest dimension.

The nanoparticles may be of any shape or form including, but not limited to, nanorods, spherical particles, nanowires, nano-sheets, quantum dots, and core-shell nanoparticles.

In some embodiments, the at least one metal source is metal microparticles. In such embodiments, the metal microparticles having an average size of between 1 μm and 500 μm.

The nanoparticles or microparticles are typically metallic nanoparticles, metallic microparticles, or nanoparticles or microparticles composed of a semiconductor material. In some embodiments, the nanoparticles or microparticles are composed of a metal selected from metals of Groups IIIB, IVB, VB, VIB, VIIB, VIIIB, IB or IIB of block d of the Periodic Table of Elements. In other embodiments, said metallic nanoparticles or microparticles are selected from Sc, Ti, V, Cr, Mn, Fe, Ni, Cu, Zn, Y, Zr, Nb, Tc, Ru, Mo, Rh, W, Au, Pt, Pd, Ag, Mn, Co, Cd, Hf, Ta, Re, Os, Al, Sn, In, Ga and Ir.

In some other embodiments, said metallic nanoparticles or microparticles are selected from Cu, Ni, Ag, Au, Pt, Pd, Al, Fe, Co, Ti, Zn, In, Sn and Ga.

In yet other embodiments, said metallic nanoparticles or microparticles are selected from Cu, Ni and Ag nanoparticles.

In some embodiments, said metallic nanoparticles or microparticles are selected from Ag and Cu nanoparticles.

In other embodiments, the metallic nanoparticles or microparticles are Ag nanoparticles.

In some embodiments, the at least one metal source is a metal precursor selected to be convertible in-situ into a metal by a chemical or electrochemical process. For example, the ink may contain AgNO₃, which after reduction upon contact with a reducer such as ascorbic acid, forms silver particles or nanoparticles. The metal precursor may also be reduced into corresponding metal by reduction of the metal precursor in the presence of a suitable photoinitiator and a radiation source. Thus, in some embodiments, the metal precursor is selected to be convertible into any one of the metals recited hereinabove. In some embodiments, the metal precursor is a salt form of any one metal recited hereinabove.

In some embodiments, the metal salt is comprised of an inorganic or organic anion and an inorganic or organic cation.

In some embodiments, the anion is inorganic. Non-limiting examples of inorganic anions include HO⁻, F⁻, Cl⁻, Br⁻, I⁻, NO₂⁻, NO₃⁻, ClO₄⁻, SO₄²⁻, SO₃⁻, PO₄⁻ and CO₃²⁻.

In some embodiments, the anion is organic. Non-limiting examples of organic anions include acetate (CH₃COO⁻), formate (HCOO⁻), citrate (C₃H₅O(COO)₃⁻³), acetylacetonate, lactate (CH₃CH(OH)COO⁻), oxalate ((COO)₂⁻²) and any derivative of the aforementioned.

In some embodiments, the metal salt is not a metal oxide. In some embodiments, the metal salt is a metal oxide.

In some embodiments, the metal salt is a salt of copper. Non limiting examples of copper metal salts include copper formate, copper citrate, copper acetate, copper nitrate, copper acetylacetonate, copper perchlorate, copper chloride, copper sulfate, copper carbonate, copper hydroxide, copper sulfide or any other copper salt and the mixtures thereof.

In some embodiments, the metal salt is a salt of nickel. Non-limiting examples of nickel metal salts include nickel formate, nickel citrate, nickel acetate, nickel nitrate, nickel acetylacetonate, nickel perchlorate, nickel chloride, nickel sulfate, nickel carbonate, nickel hydroxide or any other nickel salts and the mixtures thereof.

In some embodiments, the metal salt is a salt of silver. Non-limiting examples of silver metal salts include silver oxalate, silver lactate, silver nitrate, silver formate or any other silver salt and their mixtures.

In other embodiments, the metal salt is selected from indium(III) acetate, indium(III) chloride, indium(III) nitrate; iron(II) chloride, iron(III) chloride, iron(II) acetate, gallium(III) acetylacetonate, gallium(II) chloride, gallium(III) chloride, gallium(III) nitrate; aluminum(III) chloride, aluminum(III) stearate; silver nitrate, silver chloride; dimethlyzinc, diethylzinc, zinc chloride, tin(II) chloride, tin(IV) chloride, tin(II) acetylacetonate, tin(II) acetate; lead(II) acetate, lead(II) acetlylacetonate, lead(II) chloride, lead(II) nitrate and PbS.

In some embodiments, the method may thus comprise an additional step of converting a metal precursor into a metal form which may thereafter be sintered.

Once the pattern or structure is printed and polymerized, the step of rendering the metal source continuous and electrically conductive, by sintering or reduction may ensue, in order to transform the pattern into a conductive pattern. The converting of the pattern containing the at least one metal source, to a continuous conductive metal pattern or structure, may optionally be ensued, by sintering in case of nanoparticles and/or microparticles; or by reduction process and then optionally sintering in case of metal precursor.

The sintering of the nanoparticles or microparticles may be carried out after each printing and curing step, or after printing and curing multiple layers. Typically, the sintering may be achieved by any sintering process, such as thermal sintering, laser sintering, chemical sintering or photonic sintering. In some embodiments, thermal sintering may be performed on the partially cured pattern or on any fully cured pattern in order to cause destruction of the organic material (cured polymer that functions as an insulator); alternatively, plasma treatment, microwave treatment or treatment or any other source of thermal radiation may be employed.

In some embodiments, sintering of the nanoparticles or microparticles in the pattern may be achieved at low temperatures, typically at room temperature.

In some embodiments, at least one sintering agent may be used for achieving efficient sintering. In some embodiments, sintering with at least one sintering agent is carried out at room temperature (23-30° C.).

The sintering may be performed during or after washing away part of the unpolymerized components, such as, unreacted monomers, solvents, water, polymers, soluble fillers, surfactants and polymerization initiators.

The sintering agent being a material capable of coagulation or coalescence of the nanoparticles under specified conditions. The sintering agents may be selected amongst salts, e.g., agents containing chloride ions such as KCl, NaCl, MgCl₂, AlCl₃, LiCl, CaCl₂; organic or inorganic acids, e.g., HCl, H₂SO₄, HNO₃, H₃PO₄, acetic acid, acrylic acid; and organic or inorganic bases, e.g., ammonia, organic amines (e.g., aminomethyl propanol (AMP)), NaOH and KOH. In some embodiments, the sintering agent is NaCl.

In some embodiments, the sintering agent molar concentration is between about 0.001 mM to 5M of the formulation.

In some embodiments, the sintering is achievable at a temperature lower than 130° C. In other embodiments, the sintering is affected at room temperature or at a temperature lower than 120, 110, 100, 90, 80, 70, 60, 50, 40 or 30° C.

In some embodiment the sintering is performed during printing while the metal source is exposed to light.

In other embodiments, sintering is achieved at room temperature (i.e., 23-30° C.).

According to the invention, the method of printing a three-dimensional pattern may be achieved on a surface region of a substrate. The term “surface region” refers to any region or section or area of a substrate surface. In some embodiments, the surface region is a single region or area of the surface. In other embodiments, the term region refers to multiple regions or areas of the substrate surface. In some embodiments, the surface region is a plurality of spaced apart regions of said substrate, or a continuous region on said substrate, or the full surface of the substrate.

In some embodiments, where a pattern is formed on two or more regions of a surface, the two or more regions may be each on the same face of the substrate surface or on opposite faces of said substrate.

The regions may be of any predetermined size or shape. The regions may be in the form of a desired predetermined pattern to create a desired structure of products. In some embodiments, the pattern is a pattern of an electronic circuit.

In accordance with the method of the invention, one or more layers of an ink formulation containing nanoparticles or microparticles may be formed, e.g., printed, on a region of the surface substrate, each layer rendered conductive after a sintering on a preceding cured pattern, thereby obtaining a conductive pattern on a region of the substrate surface.

The substrate, on top of which a printed pattern is formed, may be any substrate which is stable and remains undamaged under the curing and sintering conditions employed by the method of the present invention. In most general terms, the substrate may be of a solid material such as metal, glass, paper, an inorganic or organic semiconductor material, a polymeric material or a ceramic surface, and any one or more substrate of a device such as an electronic device, and optical device, an opto-electronic device, a photoconductive device, an energy storage device, a fuel cell, a solar cell device, a power source device, and others. The surface material, being the top-most material of the substrate on which the film (of the first material or conductive material) is formed, may not necessarily be of the same material as the bulk of the substrate. In some embodiments, the substrate is selected amongst such having been coated with a film, coat or layer of a different material, said different material constituting the surface material of a substrate on which a pattern in formed. In other embodiments, the substrate may have a surface of a material being the same as the bulk material.

In some embodiments, where two or more patterns are formed on a substrate, at spaced-apart regions of the substrate surface, the surface at each one of said spaced-apart regions may be different. In such instances, one region may be coated with a film of a material being different from the substrate material, while in another region the surface material may be of a different material as compared to the first region, or may be of the bulk substrate material.

In some embodiments, the surface onto which the pattern is formed is selected from the group consisting of glass, silicon, metal, ceramic and plastic.

According to some embodiments of the invention, the pattern may be formed onto a surface region of a substrate by any method, including any one printing method.

The 3D structure may continue to be attached to the substrate after the printing process is complete, or the substrate may be used only during the course of the printing process and may be detached after the printing is complete.

In some embodiments, the surface may be selected to be detachable from the pattern or structure.

In another aspect, the invention provides a method of manufacturing a three-dimensional conductive pattern or object, the method comprising:
a) forming a pattern on a substrate, said pattern being composed of at least one liquid polymerizable monomer and/or oligomer, and at least one polymerization initiator;
b) affecting polymerization of a portion of said at least one liquid polymerizable monomer and/or oligomer, to obtain a partially polymerized pattern;
c) removing unpolymerized monomer and/or oligomer to form pores within the polymerized pattern;
d) filling said pores in the pattern with a metal source; and
e) rendering the metal source a continuous percolation path for electrical conductivity (i.e., converting the pattern containing the at least one metal source to a continuous conductive metal pattern or structure by sintering in case of nanoparticles and/or microparticles; or by reduction and optionally sintering in case of a metal precursor) to obtain a three-dimensional conductive pattern or object.

The 3D printing may be performed by several printing methods, such as ink-jet printing and digital light processing (DLP). In some embodiments, the printing is achieved by ink-jet printing. As used herein, the term “ink-jet printing” refers to a non-impact method for producing a pattern by the deposition of ink droplets in a pixel-by-pixel manner onto the substrate. The ink-jet technology which may be employed in a process according to the invention for depositing ink or any component thereof onto a substrate, according to any one aspect of the invention, may be any ink-jet technology known in the art, including thermal ink-jet printing, piezoelectric ink-jet printing and continuous ink-jet printing.

In accordance with the method described above, the method further comprises the step of obtaining an ink formulation. The printing composition, referred to herein as an “ink formulation”, comprises a liquid carrier and a plurality of metallic nanoparticles or microparticles. The metallic nanoparticles or microparticles may be of the same material, constitution (doped or undoped), shape and/or size.

The at least one metal source, e.g., metallic nanoparticles or microparticles, may be introduced to the liquid carrier in the form of a powder or in the form of a dispersion, wherein the dispersion may be an aqueous dispersion or an oil-based dispersion, e.g., dispersed in an oil phase comprising at least one liquid polymerizable monomer and/or oligomer, and at least one polymerization initiator. The liquid carrier may be an oil-in water or water-in-oil type emulsion, wherein the metallic particles or metal precursor are dispersed or dissolved with in each of the phases. The oil is a water immiscible liquid or a liquid with limited solubility in water.

In another embodiment in accordance with the method described above, the method further comprises the step of obtaining an ink formulation. The printing composition, referred to herein as an “ink formulation”, comprises a liquid carrier and at least one metal source, wherein the metal source may be a metal precursor converted to metal (or nanoparticles or microparticles) by sintering or by reduction, or the metal source may be a plurality of nanoparticles or microparticles. The metallic source may be of the same material, constitution (doped or undoped), shape and/or size.

As may be desired or necessitated inter alia by a particular process of printing, or the final characteristics of the 3D conductive pattern, the ink formulation may comprise one or more additional agents, components or additives such as a stabilizer, at least one additional initiator, at least one dispersant, at least one emulsifier, at least one surfactant, a coloring material, a rheological agent, a humidifier, a filler and a wetting agent.

In some embodiments, the ink formulation further comprises a stabilizer.

In some embodiments, the nanoparticles or microparticles may be stabilized in the formulation by one or more stabilizers (dispersing agents, dispersants) to prevent aggregation and/or agglomeration of the nanoparticles and to enable a stable dispersion. Such materials may be selected amongst surfactants and/or polymers. The stabilizer may have ionic or non-ionic functional groups, or a block co-polymer containing both. It may also be a volatile stabilizer which evaporates during the curing process; thus enabling higher conductivities after the decomposition and sintering of the pattern.

The resulting dispersion of the metallic particles may thereafter undergo a sintering process by the methods described above.

The dispersing agent may be selected amongst polyelectrolytes, polymeric materials and surfactants. Representative examples of such dispersants include, without limitation, polycarboxylic acid esters, unsaturated polyamides, polycarboxylic acids, polycarboxylate, alkyl amine salts of polycarboxylic acids, polyacrylate dispersants, polyethyleneimine dispersants, polyethylene oxide derivatives, polyurethane based dispersants and co-polymers of the above-listed polymers.

In some embodiments, the stabilizer is a polyacrylate salt.

In yet another aspect, the invention provides a conductive pattern obtainable by the above method.

The conductive pattern obtained by the method of the invention is achieved by printing multiple layers of ink formulation, followed by performing on each layer immediately after it is printed, a curing process, and then optionally a sintering process on one or more layers in order to increase the conductivity of the pattern. Along with an increase in the number of layers, the vertical wall height increases substantially, whereas the horizontal width remains narrow, and thereby, obtaining a structure of high aspect ratio.

As the process of the invention permits layering of an infinite number of ink layers (repetitions of step (a) in the above process) on a surface region, the resulting pattern with a defined aspect ratio and conductivity or the size and dimensions of the final printed object may be easily tailored. As a person versed in the art would additionally understand, the process of the invention requires curing to be carried out on only a portion of the monomers/oligomers in the formed pattern, thus allowing nanoparticles or microparticles sintering to reach completion. Following the sintering of the last material layer, the pattern may be thermally treated or washed in order to remove the unreacted monomers and/or oligomers and further remove the polymerized material, leaving behind the sintered pattern decorated by material voids (previously occupied by the unreacted monomers and/or oligomers and the polymerized material). These voids may be further filled with metal source which converts into continuous metallic 3D structure.

Thus, the invention also provides a three-dimensional conductive metallic pattern or object, the pattern being characterized by a plurality of material voids, each void being of random size and shape and randomly distributed in said pattern, wherein said pattern having an aspect ratio of between 0.5-100. The material voids are typically in the form of surface depressions and inner cavities. The inner cavities may be interconnected.

The conductive pattern or object formed by any one process of the invention, is characterized by high aspect ratio (thus rendering it 3D) and high conductivity. The aspect ratio of a pattern defines a ratio of the height of pattern to its width. A printed pattern with a high aspect ratio is characterized by a long vertical axis and a short horizontal width.

In some embodiments, the aspect ratio of a pattern according to the invention is between 0.5-100.

In some embodiments, the resistivity of a pattern according to the invention is in the range of 1.6×10⁻⁴-1.2×10⁻⁶ ohm·cm.

In some other embodiments, the pattern of the invention is composed of 3 to many thousands of layers, e.g., 200,000, 100,000, etc. In some embodiments, the number of layers does not exceed 200,000. In some embodiments, the number of layers does not exceed 100,000.

In some other embodiments, the pattern of the invention is composed of 3 to 1,000 layers.

In some embodiments, the pattern has a height of 1 μm to 50 cm. In some embodiments, the height may reach up to 400 μm, or even 50 cm.

In other embodiments, the 3D structure has an average width of 10 μm to 50 cm.

The pores defining the surface and inner structure of the pattern of the invention may be filled with any one material to render the pattern any one added quality or characteristic. In some embodiments, the pores are filled with air or with a material that may be washed away.

Thus, the invention also provides a pattern or a 3D structure comprising a metal and at least one material selected from a plastic material said at least one material occupying voids in said metal, said voids being in a form selected from surface depressions and inner cavities.

Any pattern obtained by a process of the present invention may be used widely for fabrication of various 3D structures and functional high aspect ratio coatings and functional patterns in devices, such as sensors, optoelectronic devices, solar cells, electrodes, RFID tags, antennas, electroluminescent devices, power sources and connectors for circuit boards. The 3D conductive structures may be either composed of a single material, or may be composed of different materials in different regions or parts of the structure, wherein only certain regions or parts are conductive. This may be achieved for example by printing a 3D structure with materials without the conductive materials, followed by printing layers of conductive materials by the methods and materials described above.

Thus, the invention also provides a device or a 3D structure comprising at least one surface region having thereon a pattern according to the invention.

When making an ink formulation according to the invention or for use in accordance with a process of the invention, the nanoparticles, microparticles or metal precursors may be pre-formulated in a solid or liquid medium. In some embodiments, the medium is a liquid medium selected from an aqueous medium (wherein the medium is water or containing water; the water may be of a variety of purities, e.g., distilled, deionized, etc) or an organic medium, comprising or consisting at least one monomer and/or oligomer for affecting polymerization of a pattern.

Prior to dispersion of the nanoparticles or microparticles, the nanoparticles may be lyophilized to obtain a powder.

In some embodiments, the nanoparticles are dispersed in an emulsion comprising at least one un-polymerizable liquid, at least one monomer, at least one oligomer or a combination thereof. In some embodiments, the at least one monomer or at least one oligomer are water-insoluble. In some embodiments the at least one un-polymerizable liquid is water.

The ink formulation may be in a liquid form. In some embodiments, said ink formulation is solvent free. In other embodiments, said ink formulation is free of water.

According to the invention, the ink formulation may be provided as an oil-in-water emulsion; comprising a water phase, i.e., aqueous dispersion of a metallic source, and an oil phase, i.e., polymerizable liquid of monomers and/or oligomers and at least one polymerized initiator. The oil phase is mixed with the water phase to obtain oil droplets which are composed of water-insoluble monomers and/or oligomers and an aqueous dispersion of nanoparticles or microparticles. The emulsion may be formed by various methods known in the art for making emulsions (such as homogenizers, sonicators, high pressure homogenizers), while using suitable emulsifiers.

In some embodiments, the oil phase may further contain at least one surfactant. The surfactant may be selected amongst ionic or non-ionic surfactants. In some embodiments, the at least one surfactant is selected from polysorbates, alkyl polyglycol ethers, alkyl phenol polyglycol ethers, e.g., ethoxylation products of octyl- or nonylphenol, diisopropyl phenol, triisopropyl phenol; sulfosuccinate salts, e.g., disodium ethoxylated nonylphenol ester of sulfosuccinic acid, disodium n-octyldecyl sulfosuccinate, sodium dioctyl sulfosuccinate, and the like. In some embodiments, the surfactant is selected from ethoxylated sorbitan monooleate (Tween 80), sodium dodecyl sulfate, polyglycerol esters and ethoxilated alcohols (Brij), sorbitan molooleate (Span 80) and combinations thereof.

In some embodiments, the emulsion is prepared by polyvinyl pyrrolidone and its derivatives and polyvinyl alcohol.

In some embodiments, the method as herein described, wherein the ink formulation is an emulsion-dispersion formulation comprising:
(a) at least one metal source, e.g., metal nanoparticles, dispersed in an organic or aqueous medium and
(b) an oil-based emulsion comprising at least one monomer, at least one oligomer or combinations thereof and at least one polymerization initiator.

In another aspect, the invention provides an emulsion-dispersion (or oil-in-water) ink formulation comprising at least one metal source, e.g., nanoparticles, dispersed in an oil-based emulsion comprising at least one monomer, at least one oligomer or combinations thereof and at least one polymerization initiator.

The emulsion-dispersion ink formulation employed in the invention, is an oil-in-water emulsion prepared by first adding at least one metal source into an aqueous dispersion, and optionally, in the presence of at least one stabilizer (e.g., polyacrylic salts), in a hydrophobic material (i.e., the emulsion containing at least one monomer, at least one oligomer or combinations thereof and at least one polymerization initiator). The dispersion:emulsion, is prepared by any dispersing method, as known in the art (e.g., stirring or mixing), at a dispersion ratio of 1:10 to 10:1. Alternatively, the dispersion:emulsion ratio is 2:3. A surfactant, such as but not limited to, Tween 80, may be added to the mixed emulsion-dispersion ink formulation.

In yet another aspect, the invention provides an ink formulation comprising metallic nanoparticles or metal precursors, at least one liquid polymerizable monomer and/or oligomer, and at least one photoinitiator for affecting polymerization of said at least one liquid polymerizable monomer and/or oligomer. In some embodiments, the ink formulation is for use in three-dimensional printing.

In another aspect, the invention provides an ink formulation comprising metallic nanoparticles, at least one liquid polymerizable monomer and/or oligomer, and at least one polymerization initiator for affecting polymerization of said at least one liquid polymerizable monomer and/or oligomer, for use in the three-dimensional printing according to any one method of the invention.

As used herein, the ink formulation comprises metallic nanoparticles or metal precursors, at least one liquid polymerizable monomer and/or oligomer, and at least one polymerization initiator, each being selected as defined hereinabove.

In the preparation of an ink formulation according to the invention, the solution of monomers and/or oligomers, and the solution comprising the polymerization initiator are mixed to obtain an oil phase. Then, a dispersion of nanoparticles (e.g., prepared by mixing the pre-prepared nanoparticles powder in a medium, e.g., aqueous medium) may be added to the oil phase solution comprising the monomers/oligomers and subsequently mixed. At least one surfactant may be also introduced.

In some embodiments, the ink formulation comprises a nanoparticle load of up to 70% wt. In other embodiments, said ink formulation is characterized by nanoparticle load in the range of 25-35% wt. In further embodiments, said ink formulation is characterized by nanoparticle load in the range of 20-30% wt. The loading of the metal nanoparticles in the ink formulation is of 5, 10, 15, 20, 25, 30, 40, 50, 60 or 70% wt (or intermediate loading).

An obstacle towards achieving a printed pattern of high aspect ratio is the flow of the ink on the surface region of the substrate. The major features which affect the flow of the ink formulation on the substrate are the viscosity and the surface tension of the ink formulation. The ink formulations of the invention are characterized by a surface tension in the range of 25-60 mN/m and viscosity in the range of 3-15 cP at the jetting temperature in case on ink-jet printing. In some embodiments, the ink formulation of the invention has a viscosity of 10, 20, 30, 40, 50, 60, 70, 80, 90, 100 or 500 cPs (or intermediate viscosities) at room temperature and has a lower viscosity that fits the print-head while jetting, depending on the jetting temperature.

In some embodiments, the ink formulation has a surface tension in the range of 25-35 mN/m and viscosity in the range of 8-20 cP at the jetting temperature. The jetting temperature may be in the range of 18° C. to 90° C.

In some cases, the printed 3D object or pattern is subjected to additional heating process in order to remove the organic material, thus obtaining a metallic structure essentially without organic material. The heating can be performed in air, under specific gas composition, or under vacuum.

In case of DLP inks, the viscosity may be much higher, up to 400 cP. In some embodiment, the ink formulation is in the form of a paste having a viscosity of about 1000 cP.

In general, the ink may be a Newtonian liquid or a pseudo-plastic liquid.

In some embodiments, DLP printing (for example by Asiga Pico plus 39) may be utilized in accordance with a method of the invention, enabling the printing of 3D objects from within a bath containing polymerizable material. Typically, in such a device, the bottom of the bath is composed of a transparent plastic sheet. An Aluminum or Glass plate is lowered to the bottom of the bath until leaving a gap of about 25 um with the surface of the plastic. The LED emits micrometer size pixels of UV light, causing small pixels to polymerize and solidify on the surface of the plate. After the first layer is polymerized, the plate is raised by a few micrometers, and the next layer is polymerized. This printing process is repeated until the whole 3D structure is obtained.

The process may be conducted for a clear solution containing the monomers, oligomers and polymerization initiators, or as disclosed herein in a two phase systems such as emulsion and/or dispersion of metallic particles.

In some embodiments, the ink may not contain a metal source, which may be printed to afford a porous 3D structure that may subsequently be filled with the metal source. Subsequently thereto, the metal source may be converted to metal by sintering or by reduction, depending on the metal source.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 shows dependence of ink viscosity on silver concentration.

FIG. 2 provides HR-SEM side view images of printed dots and UV cured multi layered droplets.

FIGS. 3A-B present HR-SEM side view images of printed dots composed of 80 droplets without (FIG. 3A) and with (FIG. 3B) exposure to UV light.

FIGS. 4A-B present a 3D profile of: a 500 μm diameter pixel printed in 1, 5, 10, 20 and 30 layers (FIG. 4A—left to right, respectively) and a 200 μm width printed line composed of 1, 3, 6, 10 and 20 layers (FIG. 4B—left to right, respectively).

FIGS. 5A-B depict the effect of polymerization on the line height (FIG. 5A) and width (FIG. 5B) when printing various layers of ink with (circle symbol) and without (square symbol) UV exposure.

FIG. 6 depicts the dependence of resistance on the number of printed layers. Measurements were performed on top of the printed lines. Each layer was polymerized by exposure to LED UV for 1 sec. After the polymerization of all the layers, the line, which was 2 cm long, was dipped in 1M NaCl solution.

FIG. 7 shows the dependence of the resistance on UV exposure time of each layer (3 printed layers).

FIG. 8 presents HR-SEM images of the photo-polymerized and sintered silver line at various magnifications.

FIGS. 9A-D shows the formation of a conductive bridge by a UV polymerizable ink according to the invention. Optical images of (FIG. 9A) ink printed with UV exposure, (FIG. 9B) ink printed without UV exposure, (FIG. 9C) EL device without illumination at the bridge section and (FIG. 9D) the same bridge at higher magnification.

FIG. 10 depicts sheet resistance of film after exposure to dipping in 1M NaCl solution for a period of time.

FIG. 11 depicts the height of cured (triangle symbol) and uncured (rectangle symbol) layers of printed ink of 1 to 20 layers.

FIG. 12 depicts the width of cured (triangle symbol) and uncured (rectangle symbol) layers of printed ink of 1 to 20 layers.

FIG. 13 shows a line profile of a printed pyramid structure (˜3×3 mm base, ˜80 μm height).

FIG. 14 shows an optical 3D profile of the printed pyramid structure.

FIG. 15 shows oil droplet size as a function of oil and water stirring method.

FIG. 16 shows printed structures using 60:40 ratio of oil-in-water ink at Asiga Plus 39 printer.

FIG. 17 shows HR-SEM images of printed structures of oil-in-water emuslions at different ratios.

FIG. 18 shows the effect of oil droplet size and oil:water ratio on the surface area of the printed structure.

FIG. 19 shows printed 3D structures formed by DLP printing of oil-in-water emulsion. On the left side, a cube prior to inserting the silver nanoparticles. On the right side, a cube filled with silver NPs.

FIG. 20 shows printed 3D cube formed by DLP printing of oil-in-water emulsion, where the water phase contains 13% wt of AgNO₃ salt.

### DETAILED DESCRIPTION OF EMBODIMENTS

### I. Example 1

### Obtaining Film from Oil-in-Water (O/W) Emulsion

In preliminary experiments, the polymerization of the emulsion was tested by exposing a milliliter droplet to a curing source to a period of time sufficient to transform the polymerizable monomer into a solid polymer form.

Oil-in-water (O/W) emulsion was prepared by homogenizing the monomers in water while using Tween 80 as an emulsifier to obtain the emulsion which the droplet was taken from. The droplet was then exposed to UV light for a few seconds. The liquid droplet immediately transformed into solid, indicating that in spite of the high turbidity, the composition of the emulsion enabled polymerization.

### Silver Nanoparticles Preparation:

The synthesis of silver NP dispersion (42% wt) was performed as described by Magdassi et al. [12], yielding nanoparticles which are stabilized by polyacrylic acid sodium salt (PAA, MW 8 kD) having an average size of 14±3 nm and zeta potential of −42 mV. The resulting dispersion was then lyophilized to yield a powder of silver nanoparticles. The lyophilization was performed over a period of 24 hours, at −47±3° C. and at absolute pressure lower than 1 mbar (Labconco FreeZone 2.5 liter freeze dryer). The silver dispersion was frozen in liquid nitrogen prior to lyophilization.

### Oil-in-Water (O/W) Emulsion Preparation:

In the next step, silver nanoparticles were added to the oil emulsion by mixing the silver particles with the aqueous phase of the emulsion prior to homogenization. The resulting emulsion-dispersion system was black and opaque, compared with the white emulsion without the silver nanoparticles. Here two preliminary polymerization experiments were performed by draw-down of the emulsion-dispersion, at film thickness of ˜350 μm. It was found that exposure of a few seconds enabled the transformation of a wet film into a solid film. As expected, while performing the same experiment with a droplet, polymerization occurred only at the outer layer, due to the high opacity of the system. Therefore, the following 3D printing experiments were performed by printing multiple thin layers of the ink, followed by exposing each layer right after it was printed to a UV radiation.

### Methods of Characterization of 3D Printed Patterns

### Experimental Techniques

### Electrical Measurements

The electrical measurements were performed by Extech Milli Ohmmeter while mounting two electrodes at fixed distances, and by a four-point probe surface resistivity meter (Cascade Microtech Inc.) for printed films. The measured resistance was converted into resistivity based on the line's dimension.

### Surface Tension Measurements

The surface tension measurements were carried out by a pendant drop tensiometer (First-Ten-Angstrom 32).

### Cross-Section Profiles

The cross-section profiles of the lines were measured by a Veeco Dektak 150 Surface Profiler and by a 3D optical profiler (Bruker, Contour GT-I 3D).

### HR-SEM Imaging

The printed structures were imaged by an optical and a HR-SEM microscope (Philips, Sirion HR-SEM).

### Viscosity Measurements

Viscosity was measured using ReoScope (Thermo Haake) with a C60/lo Ti polished cone, and a glass plate at shear rates between 0.1 and 3000 l/s at 25° C.

### II. Example 2

### 3D Printing Pattern of Dots on Substrate

### Materials and Methods of Preparation

### UV Reactive Oil Phase Preparation:

The oil phase was composed of the following components:

(1) Monomers: Dipentaerythnitol Hexaacrylate (DPHA) and Trimethylolpropane Triacrylate (TMPTA) at 2:3 weight ratio.

(2) a mixture of photoinitators: Ethyl-4-dimethylaminobezoate (EDMAB) 32%, 2-Isopropylthioxanthon 13%, 2-benzyl-2 dimethylamoni-1-94-morpholinophenyl)-butanone-1 12%, dimethyl-1,2-diphenyllehan-1-one 28%, and Benzophenon 15%, all dissolved at a 1:2 weight ratio with Dipropylenglycol Diacrylate (DPGDA).

Then the two solutions of monomers and photoinitiators were mixed at a 1:1 weight ratio. The obtained oil phase was a clear solution with a yellowish color.

### Aqueous Dispersion of Nanoparticles Preparation:

The silver NPs were prepared similarly as described above in Example 1. A 30 wt % silver dispersion was prepared by mixing the silver powder in triple-distilled water and sonicated in a bath for 5 minutes.

### Oil-in-Water Emulsion Preparation:

The nanoparticles dispersion was mixed with the above reactive oil phase at a ratio of 2:3, in presence of 3% Tween 80, with Ultra-Turax homogenizer, at 13,000 rpm for 7 minutes. The final white emulsion ink had a viscosity of ˜60 cP and a surface tension of 25 mN/m.

### Pattern Printing and UV Polymerization:

3D patterns were produced by printing individual layers of the ink, each printing of each layer followed immediately by exposure to UV light (delay time less than 1 sec).

Printing was performed for several numbers of layers, by an Omnijet100 ink-jet printer (Unijet, Korea) equipped with Samsung piezoelectric printheads of 30 picoliters. After printing, each layer was exposed for 1 sec to UV light that was generated from a light emitting diode (LED) UV lamp (Integration technology, LEDZero VTwin Plus 100-250V 50/60 Hz, 395 nm) and mounted at a distance of 1 cm from the substrate.

The printing was performed on various substrate surfaces, including; glass, hydrophobicaly treated glass (dipped in Sigmacote®, SigmaAldrich), polyethelene terphtalate (PET, Jolybar, Israel) and Si wafer.

In an another experiment, the building of bridges was performed by printing the ink on top of a PEG 3400 (Sigma-Aldrich) support layer, made by placing a melted droplet of PEG on the substrate.

A four-layer electroluminescent device (PET: ITO: ZnS: BaTiO3) was manufactured as follows: On top of a transparent ITO electrode, a layer of ZnS paste (MOBIChem Scientific Engineering, Israel) was coated by Dr. Blade. After drying at 60° C., it was further coated with BaTitante paste (MOBIChem Scientific Engineering, Israel). The electrode was formed by ink-jet printing of the ink formulation as described above, directly on the BaTitante layer or, for the bridge demonstration, on a PEG support placed onto that layer.

### Pattern Sintering to Produce a Conductive Pattern:

Sintering of the various printed structures was performed by dipping the various printed substrates described above in NaCl (Sigma Aldrich) 1M solution for 10 seconds.

### Characterization of the Ink:

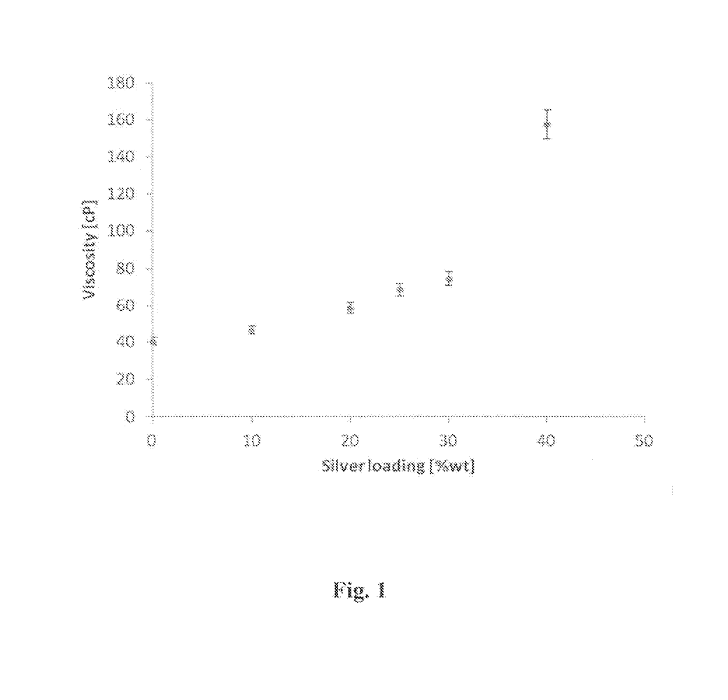

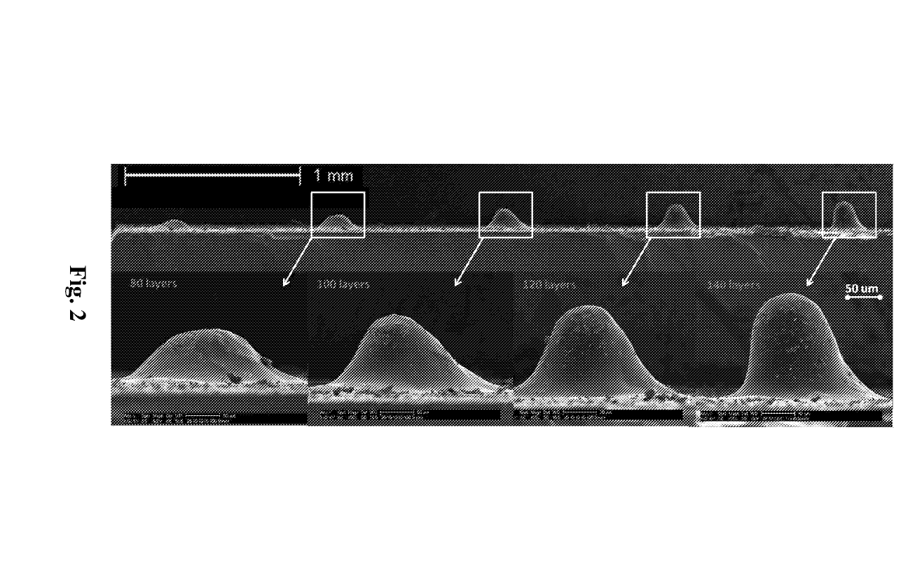

Proper ink-jet printing can be performed when the physicochemical properties of the ink matche the operation window of the print-head. Among these properties, the surface tension and viscosity are the most crucial. The surface tension of the ink was 30 mN/m, which is suitable for 3D pattern fabrication. The viscosity of the ink depends on a variety of parameters, including the fraction of the dispersed particles. In order to obtain conductive patterns it is preferable to print the inks with high metal load. However, as shown in FIG. 1, increasing the metal load causes an increase in ink viscosity, far above that which is suitable for ink-jet printing. It was found that inks with silver concentration of up to 30% wt could be printed.

3D Printing of a Pattern of Dots with and without Curing:

3D patterns were produced by printing individual layers of the ink, each printing of each layer followed immediately by exposure to UV light (delay time less than 1 sec). FIG. 2 presents a side view of printed dots, each dot being composed of a different number of printed individual droplets. It is noticed that the height of each dot increases with the increase of the number of printed layers. 140 printed layers resulted in a remarkable height of 160 μm.

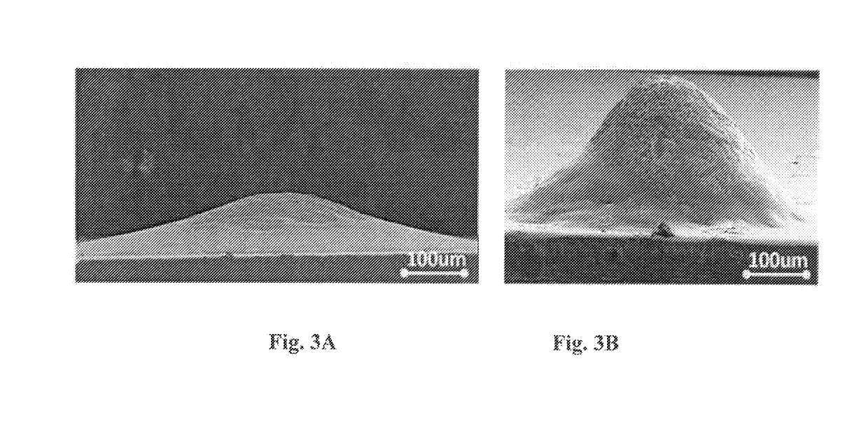

For comparison, FIG. 3 shows the difference between printed dots with and without UV exposure. It can be seen that without exposure, the dot composed of 80 layers flattens out on the surface and does not exceed a height of 60 μm. The dot with the UV polymerization reached 250 μm.

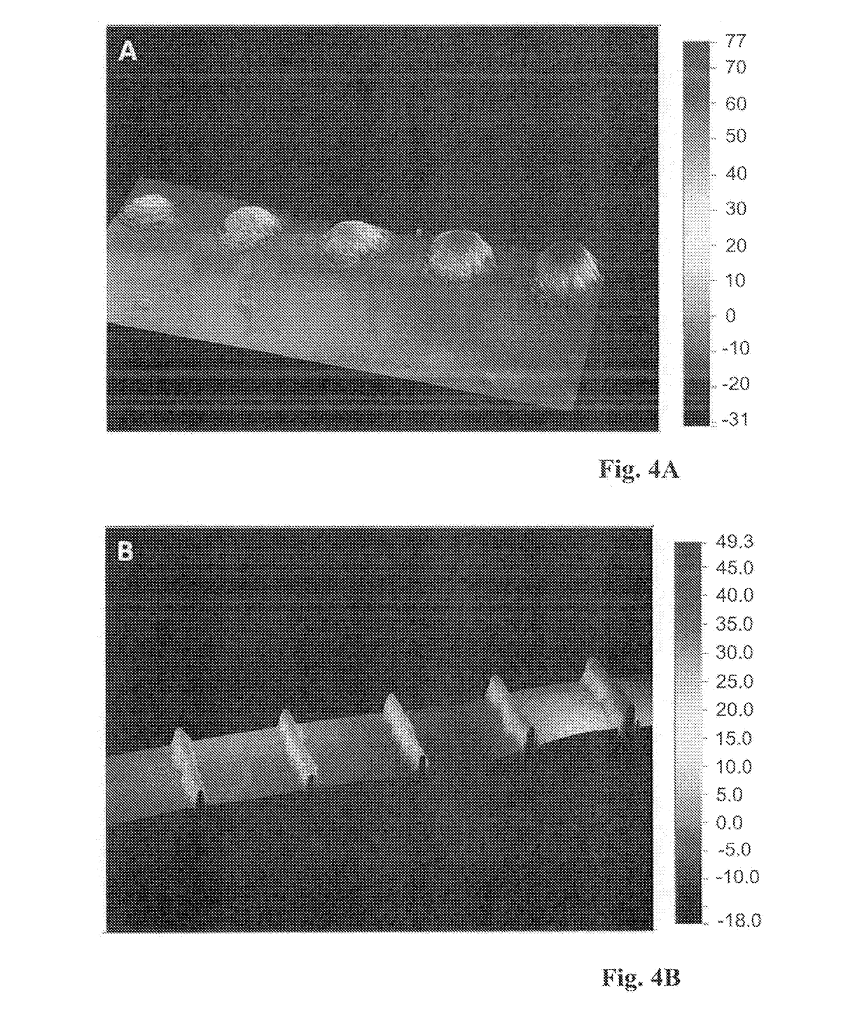

Once it was established that UV curing indeed enabled individual dots to reach great heights, lines were printed with various numbers of layers. FIG. 4 shows a 3D profile of pixels and printed lines. It can be seen that the height increases along with the number of layers printed.

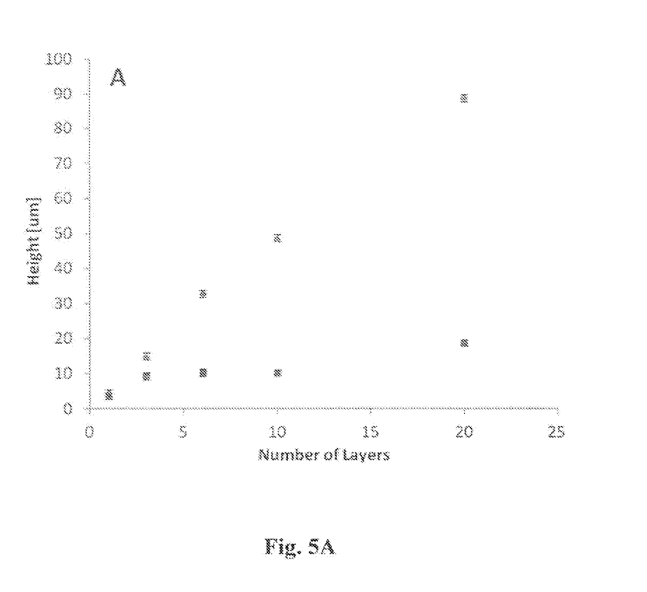

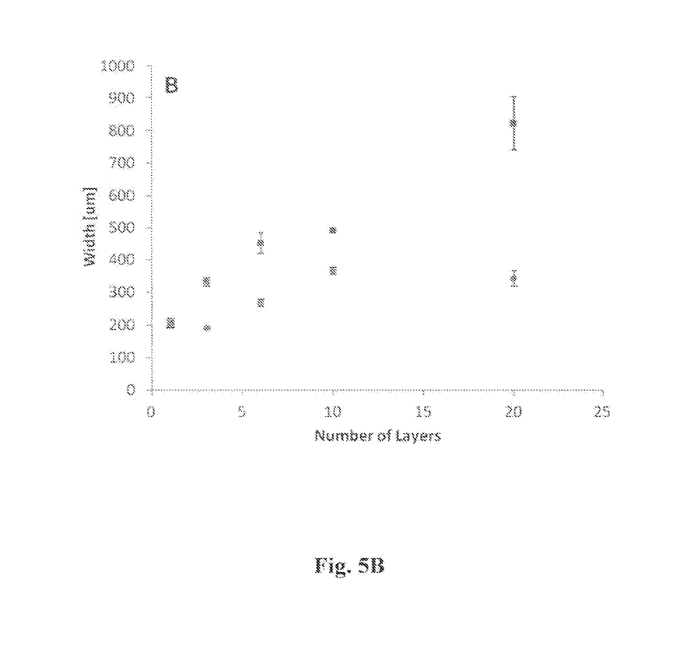

A quantitative analysis of the printed line profiles, with and without UV exposure, is presented in FIG. 5. It can be seen that as the number of printed layers increases, the height increases almost linearly and reached up to 90 μm, providing the line is exposed to UV after each layer (FIG. 5A, circle symbol). However, if there is no exposure to UV in between the printed layers, the height of the line does not exceed 20 μm. Since each line is printed with the same number of droplets, obviously the lines printed without UV exposure should be much wider than the ones with exposure (as indeed is shown in FIG. 5B). This result is important when printing narrow conductive lines in various applications, such as conductors at the front of solar cells, in order to minimize shading and thus increase the efficiency of the cells. Overall, the aspect ratio for photo-polymerized printed lines is more than 13 times higher than that of non-radiated lines.

Once the patterns are printed and polymerized, sintering must be performed in order to transform them into conductive patterns. Conventional sintering at elevated temperatures, which causes burning of the organic materials in the ink, will not be suitable, since the metal nanoparticles collapse into a thin layer and the 3D structure is destroyed. Furthermore, heating at elevated temperatures is not suitable for applications in the printed electronics field. Therefore, based on our findings that silver NPs, stabilized by PAA, undergo a sintering process by contact with chloride ions, a sintering process was utilized that will not destroy their structure. Dipping the substrate with printed silver pattern into a solution of aqueous salts, such as NaCl, may lead to resistivities of up to 5 times bulk silver. Therefore, it was expected that due to the unique composition of the emulsion-dispersion ink, dipping the polymerized printed pattern in aqueous solutions would enable penetration of water and small solutes, such as chloride ions, through the 3D structure. Initial experiments performed by dipping a polymerized film made by draw-down of ink containing 20% silver NP, indeed confirmed our assumption: after dipping the patterns in 1M NaCl solution, followed by drying at room temperature, the patterns had sheet resistance values of 7 times higher than bulk silver. The sintering process takes place due to the fact that polymerization, by the short UV exposure, is not complete and that there are still residues of water which enables the mobility of the silver NP and chloride ions which leads to percolation paths and, hence, to high conductivity.

### III. Example 3

### 3D Printing Pattern of Lines on Substrate

### Materials and Methods of Preparation

### Oil-in-Water Emulsion Preparation:

The composition of the ink formulation was similar to that described in Example 2.

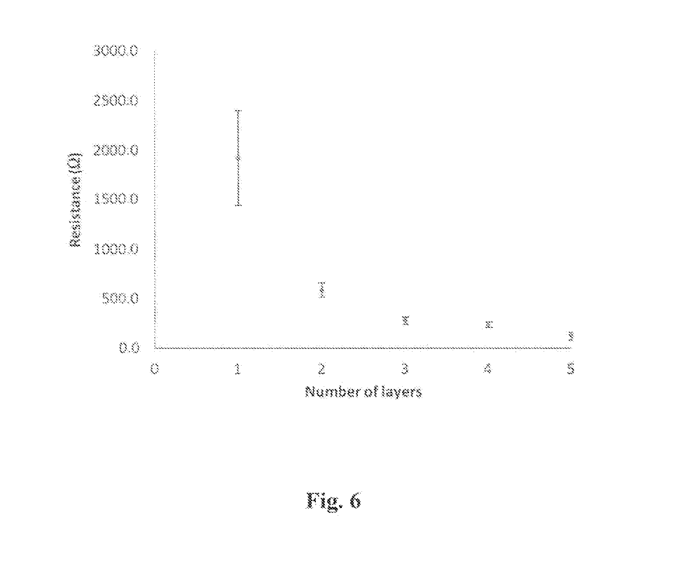

In general, the same behavior was observed for ink-jet-printed lines which were dipped into NaCl solution as observed for the printed dots of Example 2. FIG. 6 shows how the resistance of the printed lines decreases with the increase in the number of printed layers (and subsequent increase in metal content) until it reaches a minimum of about 120 ohms. Without being bound by theory, since the resistance measurement was performed by contacting the multimeter probes on top of the printed line, it could be that the upper layer was composed of a polymer, which is an insulator, above the nanoparticles, leading to resistance lower than the actual situation. Therefore, the ink was printed on top of two copper electrodes and the resistance between them was measured. For a printed line with length similar to the previously measured line (measurement “on top”), the measured resistance was much lower, only 9 ohms (measurement “in between copper electrodes”). This value corresponds to 3% bulk silver.

### Curing Time Effect on Conductivity

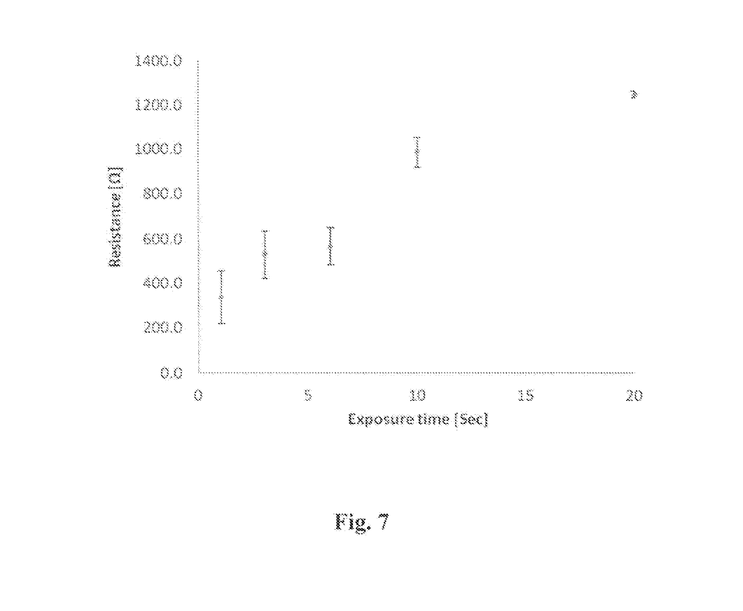

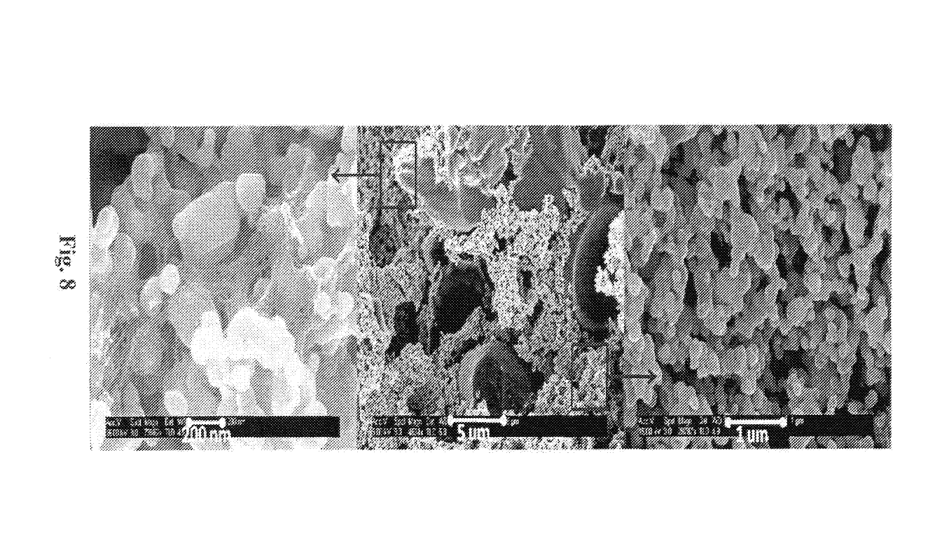

The effect of UV exposure time is presented in FIG. 7. It can be seen that increased exposure time causes an increase in resistance. If the UV exposure time was more than 30 sec, no conductivity was obtained after dipping the line at 1M NaCl solution. This is most probably due to the more complete polymerization process which prevents the penetration of the chloride ions through the polymeric matrix. The internal structure of the printed and sintered lines is shown in the HR-SEM images presented in FIG. 8. The structure is actually composed of two separated networks, one of sintered silver nanoparticles, which provides the conductivity, and one of the organic polymer, which provides the structural strength.

### IV. Example 4

### 3D Printing of Conductive Bridge and Electroluminescent Device

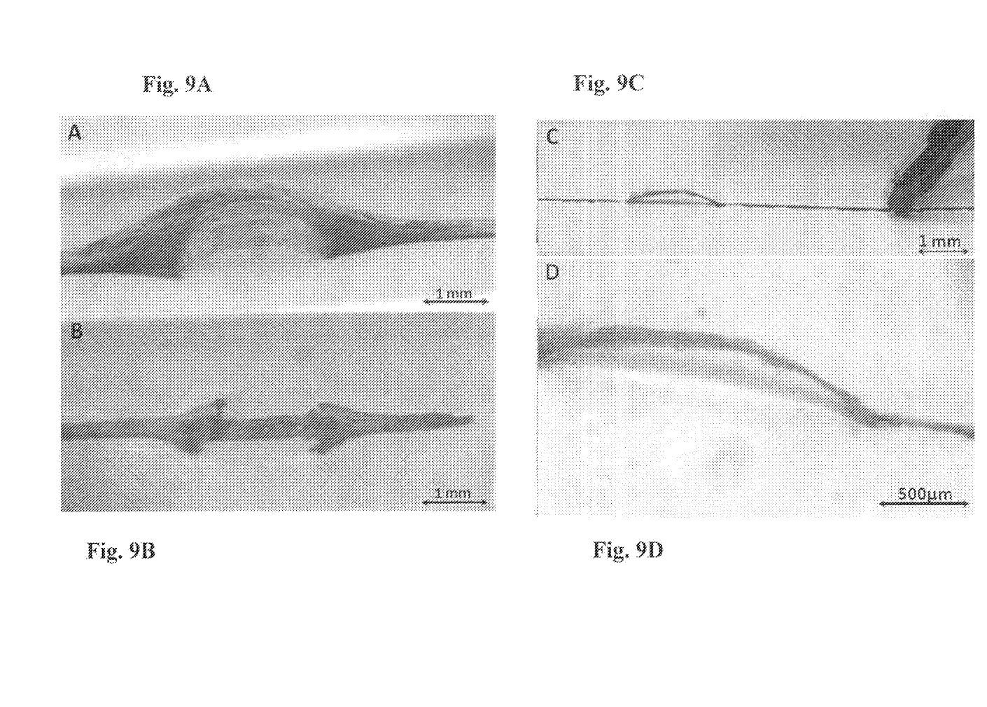

In order to show the applicability of 3D printing of conductive lines, the ink was printed as a conductive bridge on top of a support material, followed by the removal of the support. As shown in FIGS. 9A and 9B, after removal of the support, the UV-exposed ink indeed formed a bridge, while the non-exposed line collapsed onto the substrate. The use of such a bridge is also demonstrated in an electroluminescent device, in which the light was emitted only if the conductive line was in contact with the BaTitante layer. As seen in FIG. 9C there is no light beneath the bridge, while the two ends are illuminated.

### V. Example 5

### Ink-Jet Printing of Conductive 3D Structures and Sintering at Various Temperatures

A further example of a UV ink comprising polymerizable monomers and dispersed silver nanoparticles for ink-jet printing of 3D structures is presented below. Upon UV radiation the ink polymerizes and transforms from liquid to solid. Due to the metal content in the ink, the solid structure that is obtained is conductive upon performing a suitable sintering process. The sintering process may be performed at room temperature by exposure to NaCl solution, which does not harm the 3D structure. Other sintering methods are also suitable, as long as they do not cause destruction of the 3D structure.

### Preparation of Silver Dispersion:

100 gr (87.72% wt) of silver nanoparticles (Ag NP) dispersed in water (21% wt) was mixed with 14 gr (12.28% wt) of N-vinylpyrrolidone (NVP), a mono-functional monomer (Sigma-Aldrich), using a magnetic stirrer to yield a homogeneous solution. In the next step water from the mixture was evaporated from the solution using Buchi R-144 Rotary Evaporator. An optimal evaporation program was used in the following steps where each step was a linear pressure decent: Ambient 900 mbar to 150 mbar for 10 min, 150 mbar to 80 mbar in 10 min, 80 mbar to 50 mbar in 10 min, final pressure of 50 mbar was kept for additional 30 min. After observing no further evaporation of water, the vaccum was released and the Ag NP concentrate in NVP was collected. The total weight was found to be 35.3 gr where 21 gr of Ag NP, 14 gr NVP and 0.3 gr of water (yielding 60% wt Ag NP concentrate with 1% wt water).

### Preparation of UV-Silver Ink:

To a Glass Vial Wrapped in Aluminum Foil, 3.23 gr (22.22% wt) of vinyl-caprolactam, a mono-functional monomer (BASF), was added together with 2.155 gr (14.8% wt) of SR435, a tri-functional acrylic monomer (Sartomer), and 1.165 gr (8% wt) IRG819, a photo initiator (BASF). The mixture was mixed by using a stirrer in a warm bath heated to 50° C. for 10 min until a clear liquid was observed. Then, 8 gr (54.94% wt) of the above Ag NP concentrate in NVP was added dropwise to the above mixture while mixing well using the stirrer till a homogenous dispersion was achieved. At the final stage, 0.007 gr (0.04% wt) of Byk333 was added as a wetting agent. Final formulation properties as measured using Malvern NanoS surface tensiometer and HAKKE rheometer were: 10 nm average particles size, 30 dyne/cm surface tension and 26 cP respectively.

### Fabrication of Films:

Film formation and conductivity was tested by using a drawdown method. 12μ manual drawdowns (DD) were made on a glass or plastic substrates. The films were later exposed to LED light irradiation (395 nm) for duration of 30 seconds to cure the ink. Next, each sample was subjected to a sintering process.

For thermal sintering, the films were exposed to high temperature as follow: RT, 250° C., 275° C., 300° C., 310° C., 320° C., 335° C., 360° C., 400° C. and 500° C. The samples were measured for conductivity using 380562 Milliohm Meter by EXTECH. The samples were also analyzed for dimensional stability as a function of temperature to study the height and width dependency and visual analysis using SEM. 12μ and 24μ DD were made on treated PET with good adhesion to enable final conductivity analysis whiles on glass substrate this was not possible due to lack of adhesion between the ink and the glass.

For low temperature sintering, each sample was dipped in a 1M NaCl for a varying period of time: 1 min, 5 min, 10 min, 20 min, 30 min, 1 hr, 3 hr and 5 hr. The samples were then washed with distilled water to remove salt residues and dried under hot plat at 100° C. for 10 sec to remove all water. The samples were measured for conductivity using 380562 Milliohm Meter by EXTECH.

### Printing of the Ink:

The ink-jet printing was performed with Omni-Jet 100 printer. 2-3 ml of the ink was used in the printer with a SEMJET heatable print-head. The print head was heated to 55° C. to obtain optimal injection viscosity of 14 cP and the frequency was set to 1 kHz. At these conditions the drop parameters that were measured on the print user interface module (GUI) were: drop diameter 16 μm, drop volume 2.5 pl and drop velocity of 8.15 m/sec.

3D line patterns and a 3D structures composed of many layers (such as pyramid structure composed of 30 layers) were obtained, by printing layers while after each print the pattern was exposed to irradiation. The line patterns were printed with or without LED exposure (LED light emitting diode, Integration Technologies, 1 Watt output at 395 nm was used). Both the pyramid and the 3D line pattern were exposed each layer to the LED for a period of 5 seconds to achieve full cure. The samples were later analyzed by a Veeco mechanical profilometer and 3D optical profiler (Bruker, ContourGT-I 3D) for height and thickness measurements and also were visually investigated using a high resolution scanning microscope (Sirion).

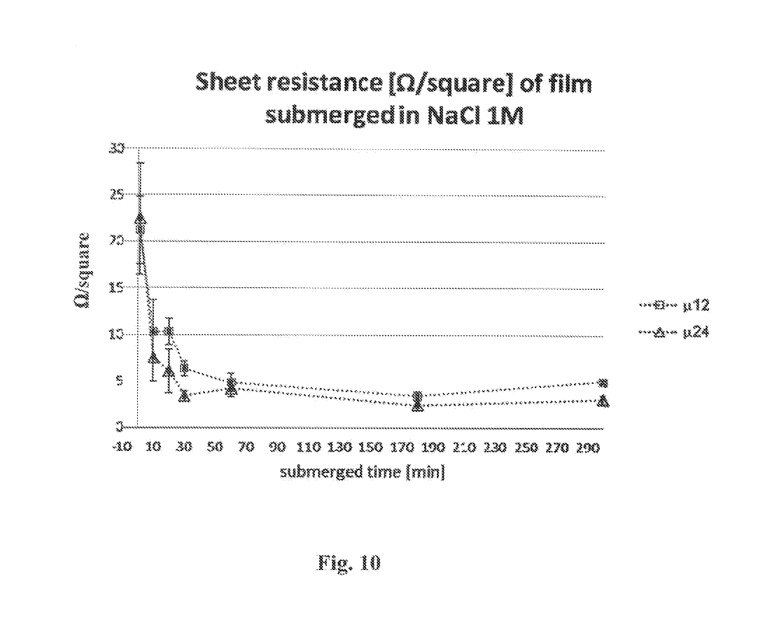

As shown in FIG. 10, the sheet resistance after dipping in 1M NaCl solution decreases with the increase of duration of dipping. After 30 min exposure time the resistivity reached a final and maximum value of ˜5 Ω/square. It was also evident that no significant difference exists between thickness of layers, 12 and 24μ.

It should be noted that resistivity without exposure to NaCl could not be measured, meaning that the printed pattern was not conductive.

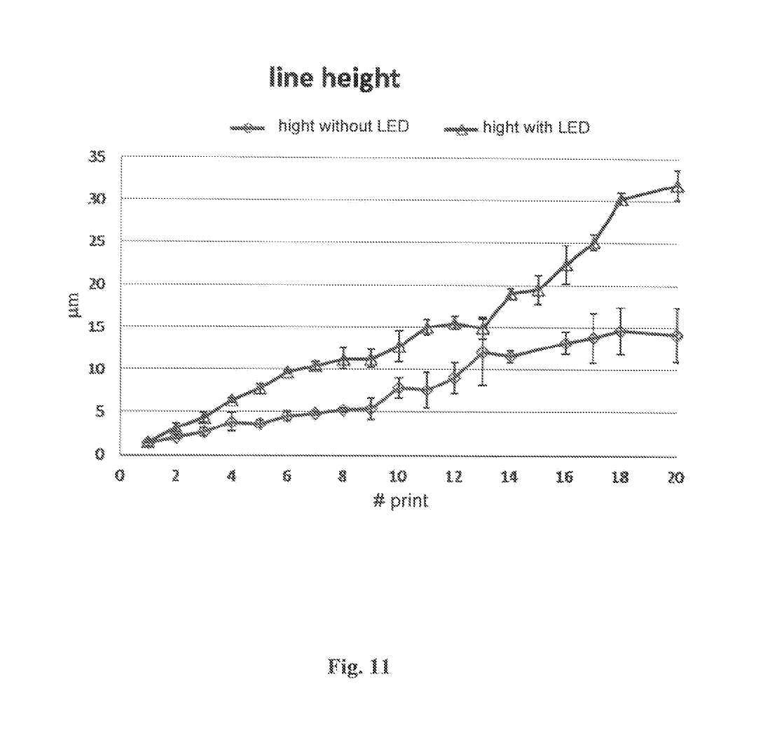

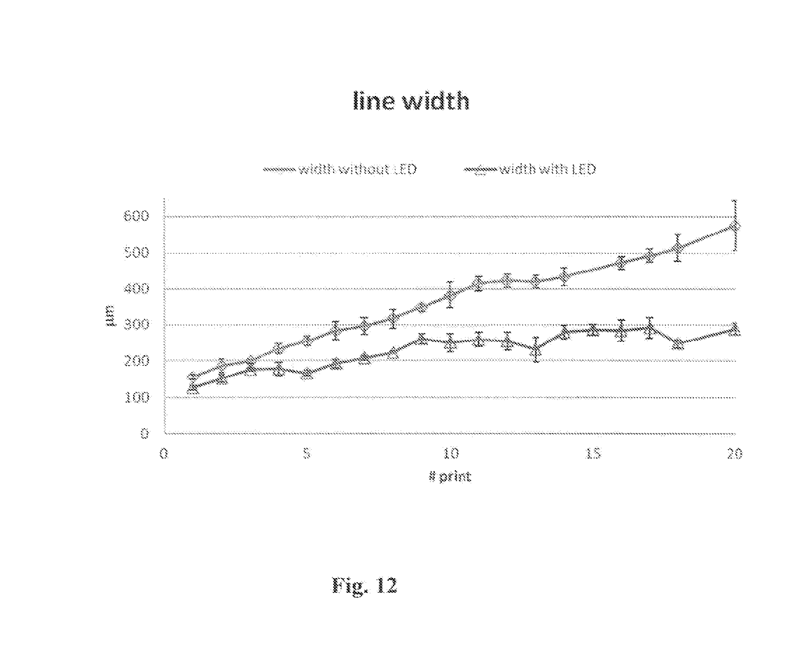

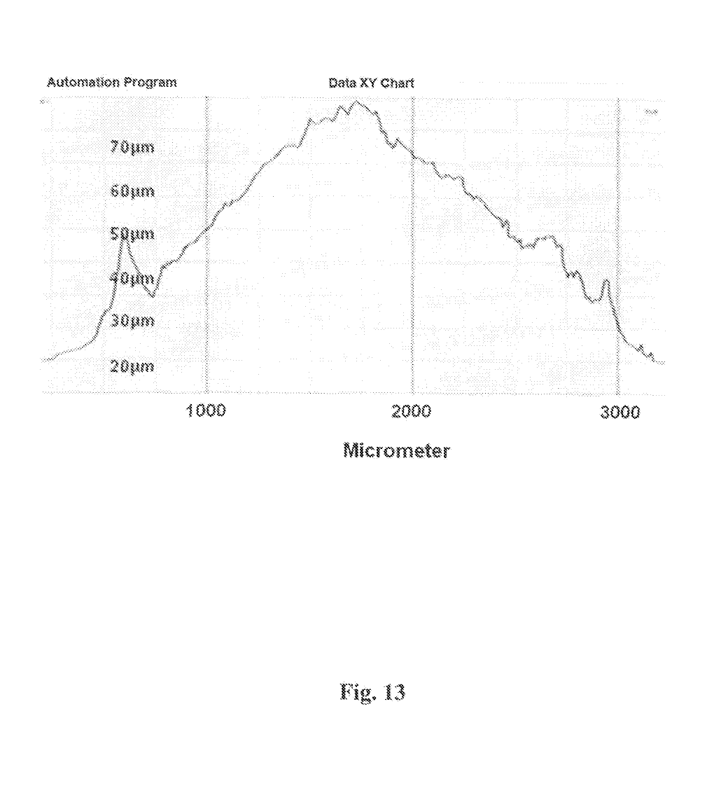

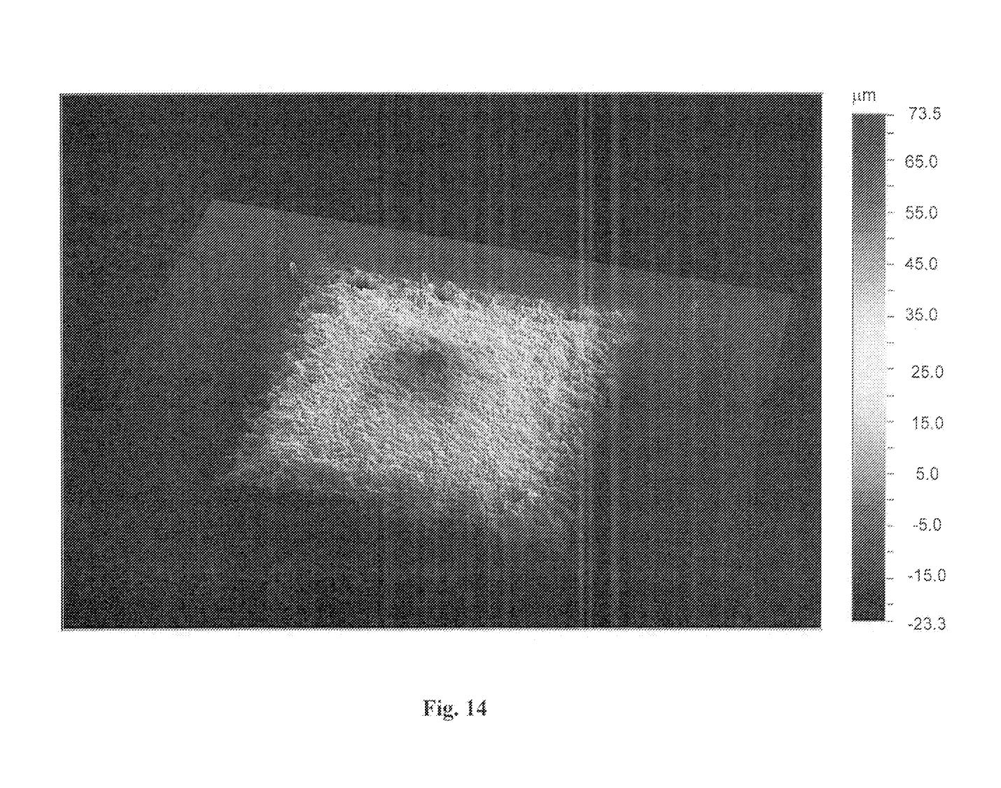

The height of cured layers of printed ink is greater than uncured ink reaching a 122% increase at 20 layers. FIG. 11 shows that printed and UV polymerized ink, builds up to 30 μm height, while the printed patterns without LED exposure spread and reach only a height of 15 μm at the same number of printed layers. As presented in FIG. 12, since the amount of printed pattern was similar in both cases, the width of the LED exposed lines (triangular symbol) is much smaller than that of the non-polymerized printed lines (rectangular symbol). As shown in FIG. 12, the width of cured layers of printed ink is smaller than uncured ink reaching a 100% increase at 20 layers. In principle, the height of the printed patterns may be very large, simply by repeating the printing-polymerization process for many times. As shown in FIGS. 13 and 14, a pyramid structure may be obtained.

### VI. Example 6

### DLP Printing of 3D Porous Structures

It was discovered that the DLP process may be applied for two phase systems such as emulsions or dispersions, in spite of the light scattering that is expected to interfere with the UV polymerization process, and in spite of the presence of material that cannot undergo the polymerization process (such as water or nanoparticles).

### UV Reactive Oil Phase Preparation:

The composition and preparation of the oil phase was similar to that described in Example 2.

### Oil-in-Water Emulsion Preparation:

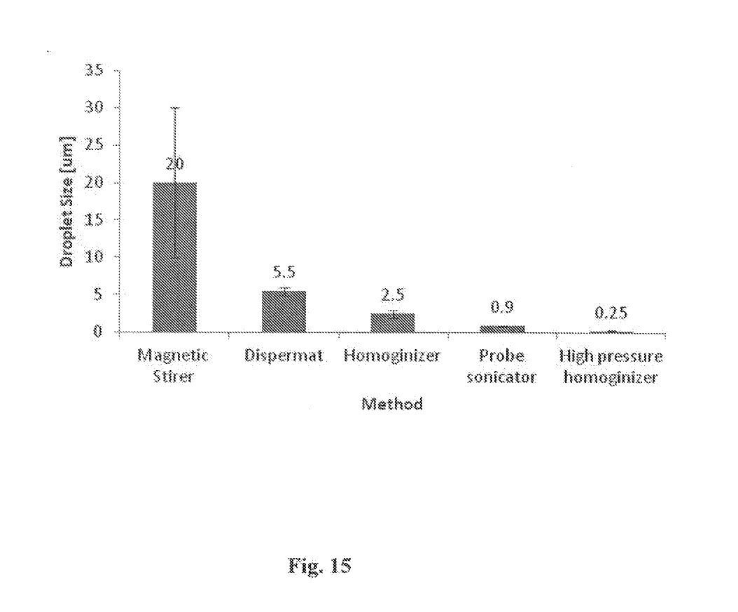

Triple-distilled water was mixed with the above reactive oil phase at ratios of 1:1, 2:3, 7:3, 8:2 in presence of 4% wt mixture of Tween 20 and Span 20 (Tween:Span ratio of 85:15). Mixing the water and oil phase in a Dispermat (CV D-51580 Reichshof, Getzmann GMBH) for 8 min at 8000 RPM provided an oil droplet size of 4-6 um (depending on the water:oil ratio). If the mixing was performed with a Ultra-Turax homogenizer, at 13,000 rpm for 7 minutes, the average oil droplet size of 1-4 μm (depending on the water:oil ratio). Mixing the water and oil phase in a tip sonicator (Somics vibra cell, VCX 750) for 30 seconds (cycle of 10 seconds on 5 seconds off) at 100% power gave a oil droplet size 900-1500 nm. A further approach for mixing the two phases was carried out by using high pressure homogenizer for 5 cycles resulted in a typical oil droplet size of 200 nm. Droplet size as a function of the various emulsion methods described above is presented in FIG. 15.

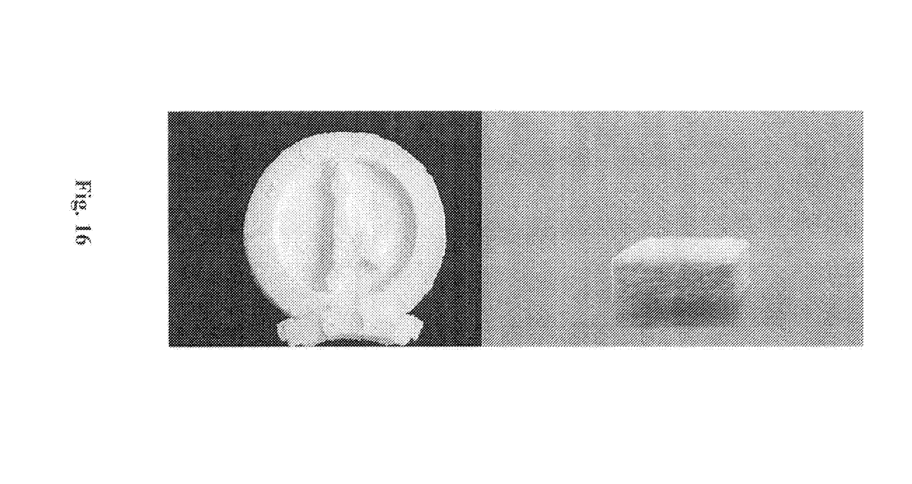

The obtained emulsion was then poured into a bath for the DLP printing (Asiga Pico plus 39). The bottom of the bath is comprised of a transparent (to Vis-UV) teflon plastic sheet. An aluminum or glass plate was lowered to the bottom of the bath until it actually touched the surface of the teflon leaving a gap of about 25 μm. The LED emits micrometer size pixels of UV light, causing small pixels to polymerize and solidify on the surface of the plate. After the first layer is finished, the plate is raised by a few micrometers, and the next layer is polymerized. This process was repeated until the whole structure was printed. A few examples of printed structures formed by DLP printing of the oil in water emulsion are presented in FIG. 16.

After the structures were printed, the residues (unpolymerized monomers, photo initiator or its decomposition products, water and solvents) were washed away by using ethanol or isopropyl alcohol and dried by nitrogen flow followed by vacuum oven at 60° C. for 1 hour.

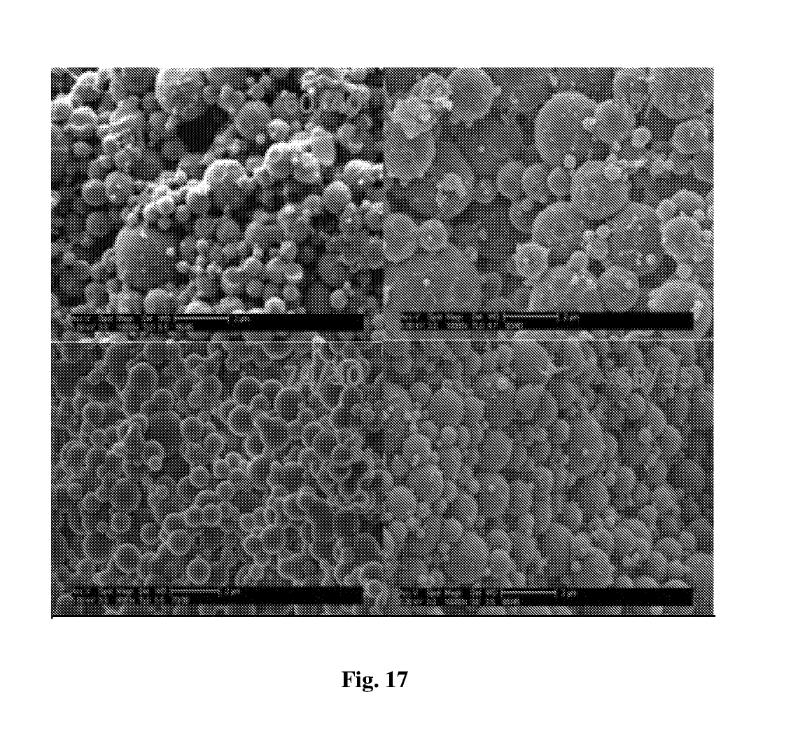

In view of the fact that during the DLP printing, most of the water phase evaporates, the resulting structure contains small voids between the polymerized oil droplets as shown in the HR-SEM images presented in FIG. 17. The voids within the entire printed object, enable forming a porous structure.

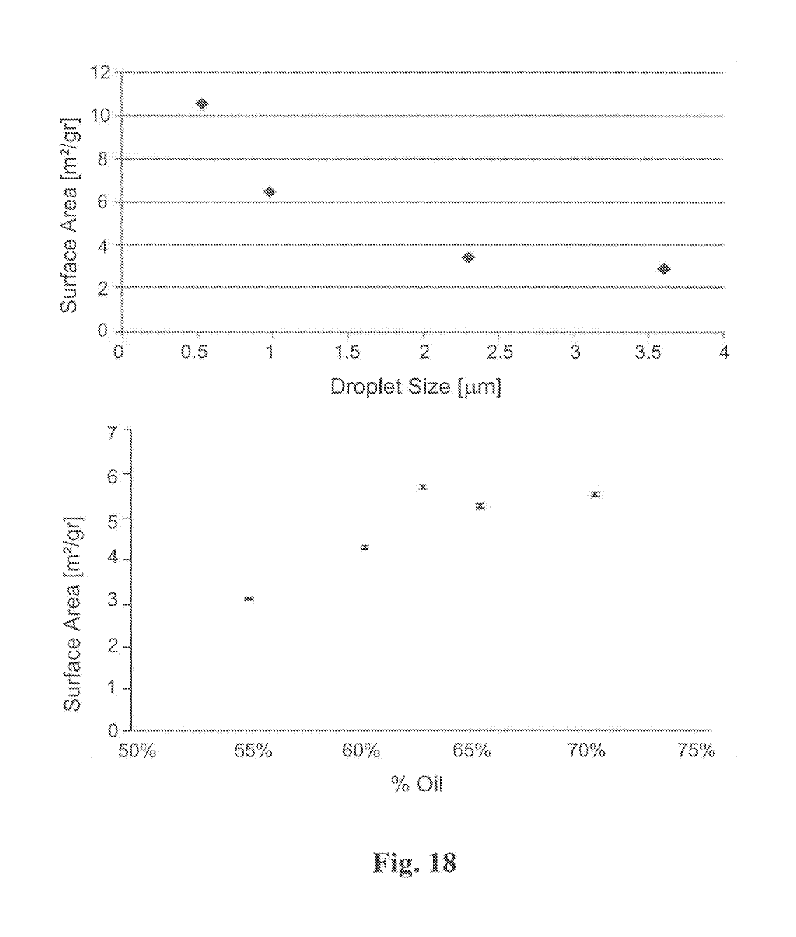

The surface area was measured as a function of oil droplet size and water and oil ratio. The results are presented in FIG. 18.

Filling of the Pores with Conductive Material

In the next step, these voids are filled with metal NP or metal precursor to achieve conductivity of the 3D printed structure.

The metallic material was inserted within the pores by one of three approaches: 1. Dipping the 3D cube in a silver nanoparticle dispersion over night under mild stirring (for example 50% wt silver nanoparticles with average particle size of 20 nm), 2. Centrifuging the cube in silver nanoparticles dispersion for specific time (for example 5 min at 1000 RPM). 3. Insertion of the dispersion under vaccum: the cube was immersed in silver nanoparticles dispersion in a small vacuumed Erlenmeyer. The vacuum may be kept for prolonged time, depending on the physicochemical properties of the dispersion and on the porosity of the printed object. It can be applied by various modes, for example by turning it on and off for 2 minutes at each cycle, and repeated for 4-20 times.

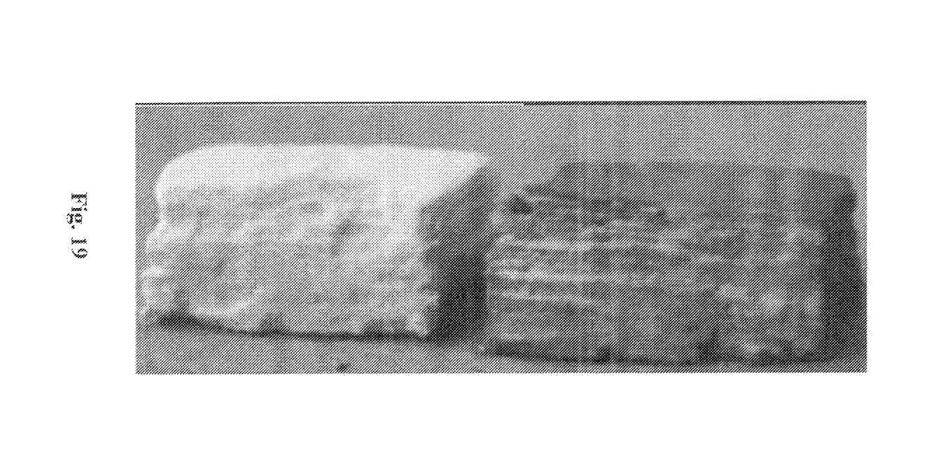

FIG. 19 (left side) demonstrates filling of the voids of the structure prepared by DLP printing as described above, with metal silver NPs (right side of FIG. 19). In order to obtain a conductive 3D printed structure, an additional step of sintering is required by a similar sintering method described in Example 2.

After the sintering, the obtained resistivity is ˜6*10⁻⁹ Ohm·meter.

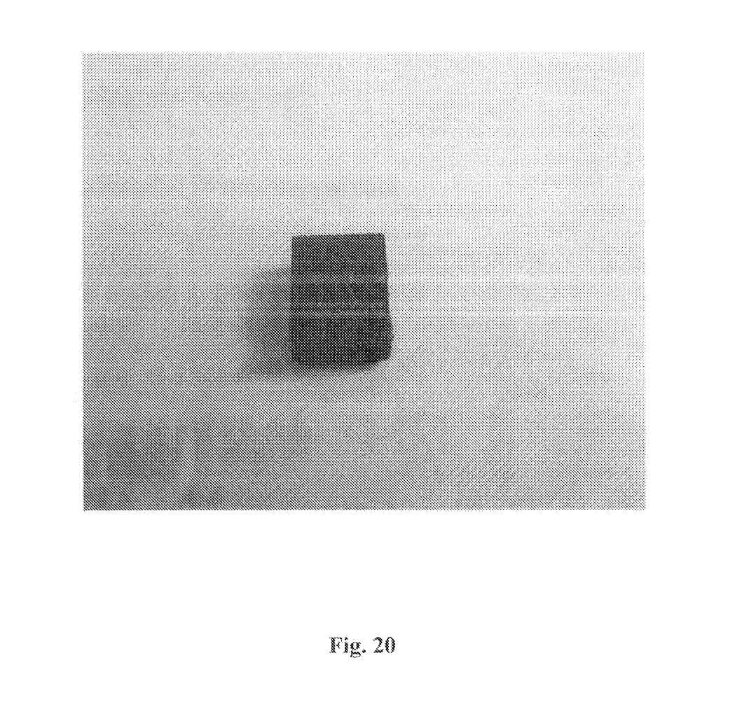

FIG. 20 presents a printed 3D cube formed by DLP printing of oil-in-water emulsion, wherein the filling of the pores with conductive material is carried out with metal precursor, wherein the water phase contains 13% wt. of AgNO₃ salt.

1.-93. (canceled)

94. A method of fabricating a three-dimensional conductive pattern or object on a surface region of a substrate, the method comprising:
a) forming a pattern on a surface region of a substrate; wherein said pattern comprising at least one metal source, at least one liquid polymerizable monomer and/or oligomer, and at least one polymerization initiator;
b) affecting polymerization of at least a portion of said at least one liquid polymerizable monomer and/or oligomer;
c) rendering the metal source a continuous percolation path for electrical conductivity;
d) forming at least one further pattern on the pattern of step (a) and repeating steps (b) and optionally (c) for one or more times to obtain a three-dimensional conductive pattern or object; and
e) optionally detaching the 3D object from the substrate to form a standalone object.

95. The method according to claim 94, wherein the pattern and the at least one further pattern comprising at least one liquid being insoluble with said at least one liquid polymerizable monomer and/or oligomer.

96. The method according to claim 95, wherein said liquid is water.

97. The method according to claim 94, wherein step (b) and optionally (c) and (d) are repeated one or more times to obtain a three-dimensional conductive pattern, wherein said pattern is characterized by an aspect ratio in the range of 0.5 to 100.

98. The method according to claim 94, wherein the three-dimensional pattern is a three-dimensional object.

99. The method according to claim 98, wherein the method further comprising detaching the three-dimensional object from the substrate surface.

100. The method according to claim 94, further comprising a step of obtaining a formulation comprising at least one metal source, at least one liquid polymerizable monomer and/or oligomer, at least one polymerization initiator, and optionally water.

101. The method according to claim 94, wherein step (d) is repeated for more than one time prior to step (c).

102. The method according to claim 94, wherein step (c) is performed after step (d) is repeated more than 2 times, more than 20 times or more than 50 times.

103. The method according to claim 94, wherein step (b) is performed for a time period sufficient to cure a portion of the polymerizable liquid.

104. The method according to claim 103, wherein step (b) is performed for a time period sufficient to cure between 1% and 99% of said at least one liquid polymerizable monomer and/or oligomer.

105. The method according to claim 94, wherein step (b) is performed by exposing the pattern containing the polymerization initiator to a radiation and/or a heat source capable of initiating polymerization.

106. The method according to claim 94, wherein the conductive three-dimensional pattern being formed by printing on a substrate selected from the group consisting of metal, glass, paper, an inorganic or organic semiconductor material, a polymeric material and a ceramic surface.

107. The method according to claim 94, wherein the pattern is formed by a printing method selected from the group consisting of ink-jet printing and digital light processing (DLP).

108. A conductive pattern or object manufactured according to the method of claim 94.

109. A method for manufacturing a three-dimensional conductive pattern or object, the method comprising:
a) forming a pattern on a substrate, said pattern being composed of at least one liquid polymerizable monomer and/or oligomer, and at least one polymerization initiator;
b) affecting polymerization of a portion of said at least one liquid polymerizable monomer and/or oligomer, to obtain a partially polymerized pattern;
c) removing unpolymerized monomer and/or oligomer to form pores within the polymerized pattern;
d) filling said pores in the pattern with a metal source; and
e) rendering the metal source a continuous percolation path for electrical conductivity to obtain a three-dimensional conductive pattern or object.

110. A three-dimensional conductive pattern or object obtainable by the method according to claim 109.

111. The pattern or object according to claim 110, having resistivity in the range of 1.6×10⁻⁴-12×10⁻⁶ ohm·cm.

112. A device comprising at least one pattern or object according to claim 111.

113. A method for manufacturing a three-dimensional conductive pattern or object, the method comprising:
a. forming a pattern on a substrate, said pattern being composed of at least one liquid polymerizable monomer and/or oligomer, at least one polymerization initiator, and at least one solvent being insoluble with said at least one liquid polymerizable monomer and/or oligomer;
b. affecting polymerization of at least a portion of said at least one liquid polymerizable monomer and/or oligomer, to obtain a polymerized pattern,
c. allowing said at least one solvent to evaporate, to thereby form material voids in said polymerized pattern;
d. introducing into the material voids at least one metal source; and
e. rendering the metal source a continuous percolation path for electrical conductivity to obtain a three-dimensional conductive pattern or object.
